(19) United States
(12) Patent Application Publication
(10) Pub. No.: US 2024/0097016 A1
(43) Pub. Date: Mar. 21, 2024

(54) COMPOUND SEMICONDUCTOR DEVICES WITH A CONDUCTIVE COMPONENT TO CONTROL ELECTRICAL CHARACTERISTICS

(71) Applicant: Analog Devices, Inc., Wilmington, MA (US)

(72) Inventors: James G. Fiorenza, Carlisle, MA (US); Daniel Piedra, Somerville, MA (US); Joshua Andrew Perozek, Somerville, MA (US)

(21) Appl. No.: 18/039,919

(22) PCT Filed: Dec. 2, 2021
(86) PCT No.: PCT/US2021/061644

§ 371 Date: Jun. 1, 2023

Related U.S. Application Data
(60) Provisional application No. 63/120,556, filed on Dec. 2, 2020.

(51) Int. Cl. H01L 29/778; H01L 29/08; H01L 29/417; H01L 29/66

(52) U.S. Cl. CPC H01L 29/7783; H01L 29/0843; H01L 29/41766; H01L 29/66462; H01L 29/7786; H01L 29/207

(57) ABSTRACT

Integrated circuits can include compound semiconductor devices having conductive components that control electrical characteristics of the compound semiconductor devices. In one or more examples, one or more conductive components can be located to increase the concentration of electrons in relation to a source electrical contact or a drain electrical contact. In one or more additional examples, a conductive component can be located to reduce the concentration of electrons in relation to a gate electrical contact. The compound semiconductor devices can include a number of compound semiconductor layers that include one or more materials having at least one Group 13 element and at least one Group 15 element.

### CLAIM OF PRIORITY

This patent application claims the benefit of priority to U.S. Provisional Application Ser. No. 63/120,556, filed Dec. 2, 2020, which is incorporated by reference herein in its entirety.

### STATEMENT REGARDING FEDERALLY SPONSORED RESEARCH

This invention was made with U.S. Government support under Agreement No. HR0011-18-3-0014, awarded by Defense Advanced Research Projects Agency. The U.S. Government has certain rights in the invention.

### FIELD OF THE DISCLOSURE

This document pertains generally, but not by way of limitation, to apparatuses and methods related to compound semiconductor devices having conductive components to control electrical characteristics of the compound semiconductor devices.

### BACKGROUND

Electronic devices, such as integrated circuits, that are constructed from compound semiconductor materials can have properties that provide operating characteristics that are improved with respect to typical silicon-based electronic devices. For example, compound semiconductor devices can have a larger bandgap and a higher critical breakdown field than silicon-based electronic devices. To illustrate, gallium nitride (GaN) can have a bandgap of about 3.2-3.4 electronvolts (eV), while silicon has a bandgap of 1.1 eV and GaN can have a critical breakdown field of 3 MV/cm, while Si has a critical breakdown field of 0.3 MV/cm. As a result, compound semiconductor devices can operate at higher voltages and be more thermally stable at higher temperatures than typical silicon-based electronic devices. Additionally, a higher electron mobility of compound semiconductor materials than silicon-based semiconductor materials can result in a faster movement of electrons in electronic devices that include compound semiconductor materials. Accordingly, electronic devices that include compound semiconductor materials can operate at higher frequencies than electronic devices that include silicon-based materials. Although electronic devices that include compound semiconductor materials have properties that can provide improvements with respect to the performance and operation of silicon-based electronic devices, the design of existing compound semiconductor-based electronic devices may be limited with respect to controlling electrical characteristics of the electronic devices, such as charge concentration and resistance.

### SUMMARY OF THE DISCLOSURE

Integrated circuits can include compound semiconductor devices having conductive components that control electrical characteristics of the compound semiconductor devices. In one or more examples, one or more conductive components can be located to increase the concentration of electrons in relation to a source electrical contact or a drain electrical contact. In one or more additional examples, a conductive component can be located to reduce the concentration of electrons in relation to a gate electrical contact. The compound semiconductor devices can include a number of compound semiconductor layers that include one or more materials having at least one Group 13 element and at least one Group 15 element.

In one or more implementations, a semiconductor device includes one or more conductive components to control electrical characteristics of the semiconductor device. The semiconductor device comprises a substrate and a first compound semiconductor layer disposed on a surface of the substrate. The first compound semiconductor layer is comprised of a first compound semiconductor material including a first group of elements having one or more first Group 13 elements and one or more first Group 15 elements. The semiconductor device also comprises a second compound semiconductor layer disposed on the first compound semiconductor layer. The second compound semiconductor layer is comprised of a second compound semiconductor material including a second group of elements different from the first group of elements. The second group of elements has one or more second Group 13 elements and one or more second Group 15 elements. In addition, the semiconductor device includes a conductive component disposed within the first compound semiconductor layer and located a distance of at least about 10 nanometers (nm) from an interface of the first compound semiconductor layer and the second compound semiconductor layer.

In one or more implementations, a process to control electrical characteristics of a semiconductor device comprises forming a first compound semiconductor layer on a substrate. The first compound semiconductor layer is comprised of a first compound semiconductor material including a first group of elements having one or more first Group 13 elements and one or more first Group 15 elements. The process also includes forming a patterned mask layer on the first compound semiconductor layer and forming one or more conductive components in the first compound semiconductor layer according to a pattern of the patterned mask layer to produce a modified first compound semiconductor layer. In addition, the process includes forming a second compound semiconductor layer over the modified first compound semiconductor layer. The second compound semiconductor layer is comprised of the first compound semiconductor material including the first group of elements having the one or more first Group 13 elements and the one or more first Group 15 elements. Further, the process includes forming a third compound semiconductor layer over the second compound semiconductor layer. The third compound semiconductor layer is comprised of a second compound semiconductor material including a second group of elements different from the first group of elements. The second group of elements has one or more second Group 13 elements and one or more second Group 15 elements.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various implementations discussed in the present document.

FIG. 1 is a diagram depicting a cross-section of at least a portion of an example integrated circuit including a compound semiconductor layer having one or more conductive components to control electrical characteristics of a compound semiconductor device.

FIG. 2 is a diagram depicting a cross-section of at least a portion of components of an integrated circuit including a compound semiconductor layer having multiple conductive components to control electrical characteristics of a compound semiconductor device.

FIG. 3 is a diagram depicting a cross-section of at least a portion of components of an additional example integrated circuit including a compound semiconductor layer having a conductive component to control electrical characteristics of a compound semiconductor device.

FIG. 4 is a diagram depicting a cross-section of at least a portion of components of an example integrated circuit including a compound semiconductor device having multiple barrier layers and one or more conductive components embedded in a compound semiconductor layer to control electrical characteristics of a compound semiconductor device.

FIG. 5 is a diagram depicting an example process to form one or more conductive components in a compound semiconductor layer.

FIG. 6 is a flow diagram depicting operations of an example process to form one or more conductive components in a compound semiconductor layer

### DETAILED DESCRIPTION

Integrated circuit components can be formed using one or more compound semiconductors. The one or more compound semiconductors can include a group of elements of a compound semiconductor material having a combination of one or more Group 13 elements and one or more Group 15 element. The integrated circuit components described herein can also comprise one or more compound semiconductors that have one or more combinations of elements that are different from a Group 13 element and a Group 15 element combination. To illustrate, integrated circuit components described herein can comprise zinc oxide (ZnO).

The integrated circuit components described herein can include transistors, such as field effect transistors. In particular examples, high electron mobility transistors (HEMTs) can be produced. HEMTs can include a first layer comprising a first compound semiconductor coupled with one or more second layers comprising one or more second compound semiconductors. The one or more second compound semiconductors can have a different bandgap and polarization field from the first compound semiconductor. The first layer and the one or more second layers can together form one or more heterostructures.

The first compound semiconductor that comprises the first layer can include a combination of one or more group 13 elements and one or more group 15 elements. For example, the first compound semiconductor can include gallium nitride (GaN). In addition, the first compound semiconductor can include aluminum nitride (AlN). Further, the first compound semiconductor can include gallium arsenide (GaAs). The first compound semiconductor can also include indium phosphide (InP).

A second compound semiconductor that comprises a second layer coupled to the first layer can include a combination of one or more group 13 elements and one or more group 15 elements. To illustrate, the second compound semiconductor can include aluminum gallium nitride (AlGaN). Additionally, the second compound semiconductor can include aluminum indium gallium nitride (AlInGaN). Further, the second compound semiconductor can include indium aluminum nitride (InAlN).

An example of a heterostructure that includes a first compound semiconductor and one or more second compound semiconductors can include a GaN layer coupled with an AlGaN layer. Another example of a heterostructure that includes a first compound semiconductor and one or more second compound semiconductors can include an AlN layer coupled with an AlN layer. Additional examples of heterostructures can include AlNGaN/AlN and InAlN/GaN. Further, various other combinations of elements from Group 13 (e.g., boron (B), aluminum (Al), gallium (Ga), indium (In) and thallium (TI)) with elements from group 15 (e.g., nitrogen (N), phosphorus (P), arsenic (As), antimony (Sb), and bismuth (Bi)) can form heterostructures that can be used to form compound semiconductor devices.

The coupling of a first layer comprising a first compound semiconductor with one or more second layers comprised of one or more second compound semiconductors can create a layer proximate to an interface between the layers that has a relatively high electron mobility. The layer can be a two-dimensional electron gas (2DEG). When a voltage is applied to a gate electrical contact of a compound semiconductor device, an electric field can be produced that can cause the movement of electrons within a channel region that includes the 2DEG. In this way, current between a source region and a drain region of a compound semiconductor device can be produced.

Existing compound semiconductor devices typically lack some of the design features that are implemented in silicon-based semiconductor devices to control electrical properties of the semiconductor devices such as resistance, charge density, and threshold voltage. For example, silicon-based semiconductor devices can include one or more doped regions to control the concentration of electrons within various regions of the silicon-based semiconductor devices. To illustrate, silicon-based semiconductor devices can include regions that have a relatively high concentration of n-type dopants with respect to the number of silicon atoms, regions that have a relatively low concentration of n-type dopants with respect to silicon atoms, and regions having an amount of p-type dopants. The regions that include the n-type dopants can have relatively higher electron concentrations and relatively lower impedance. In addition, the regions that include p-type dopants can have relatively lower electron concentrations, a relatively higher concentration of holes, and higher impedance. The location of doped regions in existing silicon-based semiconductor devices can be related to functionality of the semiconductor devices, such as enabling enhancement mode operation. Additionally, doped regions of existing silicon-based semiconductor devices can be used to modify electric fields produced during the operation of the semiconductor devices.

Dopants are not typically included in existing GaN-based HEMTs to control the electron concentration and functionality of these compound semiconductor devices because of an inability to implant and activate the n-type dopants and p-type dopants that are typically used in silicon-based semiconductor devices, such as phosphorus, arsenic, antimony, boron, aluminum, and gallium. For example, the epitaxial growth of the compound semiconductor layers can complicate the use of the n-type and p-type dopants that are typically included in silicon-based semiconductor devices. As a result, the electron concentration of existing compound semiconductor devices is relatively constant in the 2DEG along the interface between the barrier layer and the channel layer. Thus, the ability to control electron concentration and the functionality of existing compound semiconductor devices is limited due to the lack of variation in the design of these compound semiconductor devices.

Implementations described herein include compound semiconductor devices having one or more conductive components that are disposed within a channel layer to control electron concentration in the compound semiconductor device. In one or more examples, an additional 2DEG can be formed within the channel layer proximate to at least one conductive component embedded in the channel layer. In this wav, the concentration of electrons proximate to the at least one conductive component can be higher than in regions of the channel layer where a conductive component is not present. Thus, by placing one or more conductive components at one or more locations within the channel layer, the functionality of the compound semiconductor devices can be expanded. In various examples, the one or more conductive components can comprise AlN and the channel layer can include GaN.

In one or more illustrative examples, one or more conductive components can be located proximate to drain electrical contacts to lower the resistance corresponding to the drain electrical contacts. Additionally, one or more conductive components can be located proximate to source electrical contacts to lower the resistance corresponding to the source electrical contacts. Further, one or more conductive components can be located proximate to a gate region of a compound semiconductor device to deplete the 2DEG proximate to the gate region and enable the compound semiconductor device to operate as an enhancement mode device. Accordingly, rather than using n-type dopants and/or p-type dopants to control electron concentration and enable various types of functionality of semiconductor devices, implementations of the compound semiconductor devices described herein implement the use of conductive components located within the channel layer to control electrical characteristics of compound semiconductor devices. In this way, the advantages of the performance of compound semiconductor devices with respect to the performance of silicon-based semiconductor devices can be paired with the flexibility of design characteristics of silicon-based semiconductor devices.

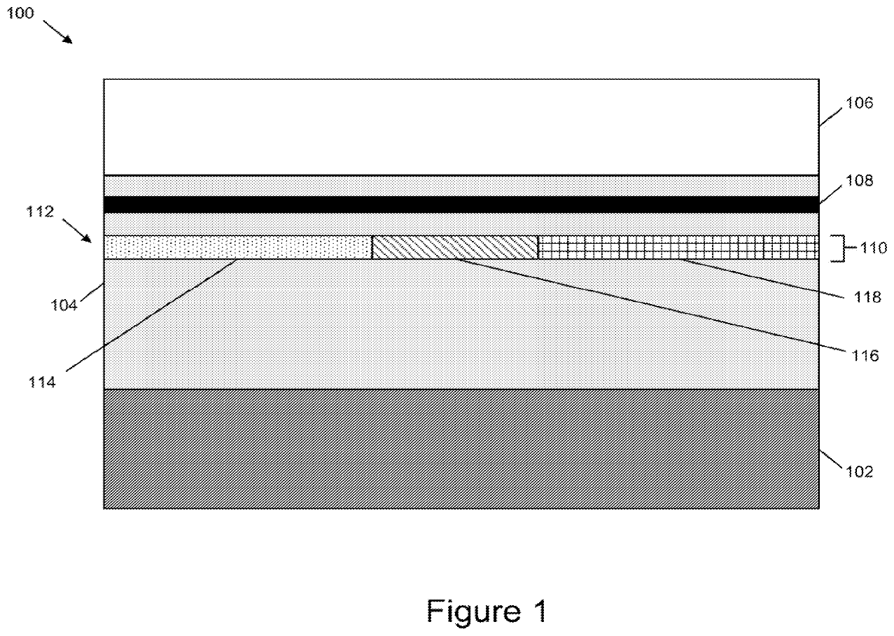

FIG. 1 is a diagram depicting a cross-section of at least a portion of an example compound semiconductor device 100 having one or more conductive components to control electrical characteristics of the one or more compound semiconductor devices. The compound semiconductor device 100 can be included in an integrated circuit and can comprise a substrate 102, compound semiconductor layers 104, and an electrical contacts region 106. The compound semiconductor layers 104 can be disposed on the substrate 102. In one or more examples, the compound semiconductor layers 104 can be grown on the substrate 102, such as via one or more epitaxial growth processes. The substrate 102 can comprise an Si-containing material. For example, the substrate 102 can be an SiC-containing substrate. Additionally, the substrate 102 can be a sapphire-containing substrate. The substrate 102 can also be an aluminum nitride-(AlN) containing substrate. Further, the substrate 102 can include polycrystalline AlN.

The compound semiconductor layers 104 can include one or more channel layers and one or more barrier layers. The one or more channel layers can comprise GaN. In one or more additional examples, the one or more channel layers can comprise GaAs. The one or more channel layers can also include InP. The one or more barrier layers can include AlGaN. In one or more further examples, the one or more barrier layers can include AlInGaN. In various examples, the compound semiconductor layers can also include one or more nucleation layers on which the one or more channel layers are formed.

Additionally, the compound semiconductor layers 104 can include a drain region, a source region, and a gate region. At least one of the drain region, the source region, or the gate region can be coupled to one or more electrical contacts included in the electrical contacts region 106. For example, the drain region can be coupled to a drain electrical contact, the source region can be coupled to a source electrical contact, and a gate region can be coupled to a gate electrical contact. The drain electrical contact, the gate electrical contact, and the source electrical contact can include one or more metals. For example, the drain electrical contact, the gate electrical contact, and the source electrical contact can include at least one of gold, one or more alloys of gold, aluminum, one or more alloys of aluminum, titanium, or one or more alloys of titanium. In addition to electrical contacts corresponding to the drain region, the gate region, and the source region, the electrical contacts region 106 can include additional metal-containing features, such as one or more interconnects, one or more field plates, one or more inductors, one or more capacitors, or one or more combinations thereof. The electrical contacts region 106 can also include one or more dielectric layers. The one or more dielectric layers can include at least one of SiN, SiO₂, Si₃N₄, or Si₂N₃.

A two-dimensional electron gas (2DEG) layer 108 can be disposed within the compound semiconductor layers 104. The 2DEG layer 108 can be a region of increased electron concentration that is located proximate to an interface of at least one barrier layer and at least one channel layer included in the compound semiconductor layers 104. An additional electron-containing region 110 can include an electron concentration profile 112. The electron concentration profile 112 can include a number of regions that correspond to a region of the compound semiconductor layers with a given electron concentration. The electron concentration of at least one region of the electron concentration profile 112 can be different from at least one additional region of the electron concentration profile 112. The electron concentration profile 112 can include a first region 114 having a first electron concentration, a second region 116 having a second electron concentration, and a third region 118 having a third electron concentration.

The electron concentration profile 112 can be produced by one or more conductive components disposed in the compound semiconductor layers 104. For example, one or more conductive components can be disposed in a channel layer included in the compound semiconductor layers 104. An additional 2DEG can be formed proximate to the one or more conductive components and increase the concentration of electrons proximate to the one or more conductive components. In various examples, the concentration of electrons in regions of the compound semiconductor layers 104 that do not include a conductive component can be relatively lower than the regions of the compound semiconductor layers 104 that do include conductive components. In one or more additional examples, a conductive component can be located within the one or more compound semiconductor layers 104 such that the conductive component depletes at least a portion of the 2DEG 108. In these scenarios, the concentration in one or more regions of the compound semiconductor layers 104 proximate to the conductive component can be relatively lower than in regions of the compound semiconductor layers 104 where the conductive component is not present.

In one or more illustrative examples, the first region 114 can correspond to a location of one or more conductive components, the second region 116 can correspond to a location where a conductive component is not present, and the third region 118 can correspond to a location of one or more conductive components. In these instances, the concentration of electrons in the first region 114 and the third region 118 can be greater than the concentration of electrons in the second region 116. In one or more additional illustrative examples, the first region 114 can correspond to a location where a conductive component is present and the second region 116 and the third region 118 can correspond to locations where a conductive component is not present. In these situations, the concentration of electrons in the first region 114 can be greater than the concentration of electrons in the second region 116 and the concentration of electrons in the third region 118. In one or more further illustrative examples, the first region 114 and the second region 116 can correspond to locations where a conductive component is not present and the third region 118 can correspond to a location where one or more conductive components are present. In these scenarios, the concentration of electrons in the third region 118 can be greater than the concentration of electrons in the first region 114 and the concentration of electrons in the second region 116.

In various examples, a distance between the 2DEG 108 and the additional electron-containing region 110 can impact the electron concentration profile 112 based on a location of one or more conductive components. For example, the concentration of electrons in a region 114, 116, 118 that includes one or more conductive components can increase in implementations where the one or more conductive components are located at least a threshold distance from the location of the 2DEG 108. In one or more examples, the threshold distance between the 2DEG 108 and the location of one or more conductive components located in the compound semiconductor layers 104 can be at least about 50 nanometers (nm). In one or more illustrative examples, the one or more conductive components disposed in the compound semiconductor layers 104 can be located from about 50 nm to about 200 nm from the 2DEG 108. In scenarios where the one or more conductive components are disposed within a specified range of distances from the 2DEG 108, the one or more conductive components can provide a region of increased electron concentration that has electrical characteristics that are similar to or the same as an n⁺ doped region of a silicon-based semiconductor device.

Additionally, in implementations where one or more conductive components are disposed in the compound semiconductor layers 104 at a distance of less than the threshold distance, the one or more conductive components can reduce the concentration of electrons in the 2DEG 108. To illustrate, one or more conductive components disposed from at least about 10 nm to no greater than about 45 nm from the 2DEG 108 can deplete the electrons included in the 2DEG 108. In one or more illustrative examples, one or more conductive components located in the second region 116 and within a specified distance of the 2DEG 108 can decrease the electron concentration of the 2DEG 108 that is proximate to the second region 116. The electrical characteristics of regions in which one or more conductive components are disposed within a threshold distance from the 2DEG 108 can be similar to or the same as an n⁻ doped region of a silicon-based semiconductor device.

In situations where one or more conductive components are located outside of a specified range of distances from the 2DEG 108, the one or more conductive components may have no effect or a minimal effect on the 2DEG 108. In one or more examples, one or more conductive components located outside of the specified range of distances from the 2DEG 108 can impact one or more electrical fields produced during operation of the compound semiconductor device 100. For example, one or more conductive components disposed in the substrate 102 can function as back-side field plates that modify an electric field profile that is generated during operation of the compound semiconductor device 100.

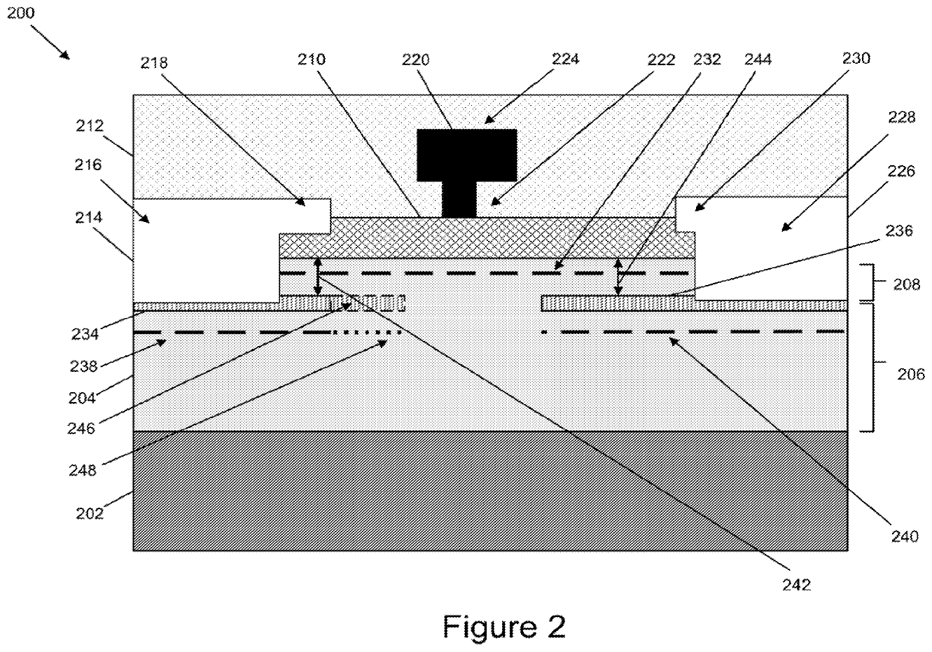

FIG. 2 is a diagram depicting a cross-section of at least a portion of components of a compound semiconductor device 200 having multiple conductive components to control electrical characteristics of the compound semiconductor device 200. The compound semiconductor device 200 can include a substrate 202. The substrate 202 can be an SiC-containing substrate. The substrate 202 can also include an Si-containing substrate. Further, the substrate 202 can include a sapphire substrate. In one or more examples, the substrate 202 can include an aluminum nitride-(AlN) containing substrate. A thickness of the substrate 202 can be from about 100 micrometers to about 800 micrometers, from about 200 micrometers to about 700 micrometers, or from about 300 micrometers to about 600 micrometers.

A first compound semiconductor layer 204 can be disposed on the substrate 202. The first compound semiconductor layer 204 can be a channel layer of the compound semiconductor device 200. The first compound semiconductor layer 204 can have a thickness from about 250 nm to about 1500 nm, from about 400 nm to about 1200 nm, from about 500 nm to about 1000 nm, from about 100 nm to about 500 nm, from about 100 nm to about 300 nm, or from about 30 nm to about 250 nm. The first compound semiconductor layer 204 can include one or more compound semiconductors. The one or more compound semiconductors of the first compound semiconductor layer 204 can include a group of elements having at least one element from Group 13 of the periodic table of elements and at least one element from Group 15 of the periodic table of elements. For example, the first compound semiconductor layer 204 can include GaN. In addition, the first compound semiconductor layer 204 can include GaAs. Further, the first compound semiconductor layer 204 can include AlN. The first compound semiconductor layer 204 can also include InP.

The first compound semiconductor layer 204 can include a first section 206 and a second section 208. The first section 206 can be formed initially and then one or more conductive components can be formed in the first section 206. After forming the first section 206, the second section 208 can be formed on the first section 206. In various examples, the second section 208 can be free of conductive components. The first section 206 and the second section 208 can have different characteristics. For example, the first section 206 can include a first concentration of dopants and the second section 208 can include a second concentration of dopants. To illustrate, the first section 206 can include a first concentration of carbon dopants and the second section 208 can include a second concentration of carbon dopants that is less than the first concentration of dopants of the first section 206. Additionally, the first section 206 and the second section 208 can include different dopants. In one or more illustrative examples, the first section 206 can include carbon dopants and the second section 208 can include silicon dopants. The differences in dopants or dopant concentration between the first section 206 and the second section 208 can minimize leakage of charge in the first compound semiconductor layer 204.

Further, the first section 206 can have a thickness that is different from a thickness of the second section 208. For example, the first section 206 can have a thickness from about 200 nm to about 1300 nm, from about 300 nm to about 1000 nm, from about 400 nm to about 800 nm, or from about 100 nm to about 500 nm. In one or more illustrative examples, the second section 208 can have a thickness from about 20 nm to about 400 nm, from about 50 nm to about 300 nm, from about 100 nm to about 250 nm, from about 50 nm to about 200 nm.

In various examples, the first section 206 can be epitaxially grown on the substrate 202. Additionally, the second section 208 can be epitaxially grown on the first section 206. Although not shown in the illustrative example of FIG. 2, a nucleation layer can be disposed on the substrate 202 and the first section 206 can be grown on the nucleation layer. The nucleation layer can have a thickness from about 10 nanometers to about 200 nanometers, from about 20 nanometers to about 100 nanometers, or from about 20 nanometers to about 80 nanometers. The nucleation layer can include an AlN-containing material.

A second compound semiconductor layer 210 can be disposed on at least a portion of the first compound semiconductor layer 204. The second compound semiconductor layer 210 can include one or more compound semiconductors. The one or more compound semiconductors can include a group of elements having at least one element from Group 13 of the periodic table of elements and at least one element from Group 15 of the periodic table of elements. For example, the second compound semiconductor layer 210 can be an AlGaN barrier layer, in various implementations. The second compound semiconductor layer 210 can also be an AlInGaN barrier layer. In addition, the second compound semiconductor layer 210 can have a thickness from about 20 nm to about 120 nm, from about 30 nm to about 100 nm, from about 40 nm to about 80 nm, or from about 20 nm to about 60 nm.

A dielectric layer 212 can be disposed on at least a portion of the second compound semiconductor layer 210. The first dielectric layer 212 can include a SiN-containing material. Although not shown in the illustrative example of FIG. 2, at least one additional dielectric layer can be disposed over the dielectric layer 212. For example, at least one additional dielectric layer can include a SiO₂ material, in one or more implementations. The at least one additional dielectric layer can also include a Si₂N₃ material or a Si₃N₄ material, in one or more additional implementations.

A source electrical contact 214 can be disposed over a source region of the compound semiconductor device 200. The source electrical contact 214 can include one or more suitable metallic materials. For example, the source electrical contact 214 can include at least one of titanium (Ti), aluminum (Al), nickel (Ni), or gold (Au). In one or more illustrative examples, the source electrical contact 214 can include a Ti/Al-containing material. In one or more additional illustrative examples, the source electrical contact 214 can include a Ti/Au-containing material. In one or more further illustrative examples, the source electrical contact 214 can include a TiN-containing material. In various examples, the source electrical contact 214 can be disposed within at least one of the first compound semiconductor layer 204, the second compound semiconductor layer 210 and the dielectric layer 212. The source electrical contact 214 can have a base region 216 and a step region 218. The step region 218 can extend away from the base region 216 toward a gate electrical contact 220. The step region 218 can contribute to a relatively low resistance junction between the source electrical contact 214 and the second compound semiconductor layer 210.

The gate electrical contact 220 can be disposed over a gate region of the second compound semiconductor layer 210. The gate electrical contact 220 can include one or more metallic materials. For example, the gate electrical contact 220 can include a titanium nitride (TiN)/Al material. The gate electrical contact 220 can also include a nickel (Ni)/gold (Au) material. Additionally, the gate electrical contact 220 can include a TiN material. In various examples, the gate electrical contact 220 can have a T-like shape with a base region 222 and a transverse portion 224 that is disposed at least substantially perpendicular with respect to the base region 222.

Further, a drain electrical contact 226 can be disposed over a drain region of the compound semiconductor device 200. The drain electrical contact 226 can include one or more suitable metallic materials. To illustrate, the drain electrical contact 226 can include at least one of titanium (Ti), aluminum (Al), nickel (Ni), or gold (Au). In one or more illustrative examples, the drain electrical contact 226 can include a Ti/Al-containing material. In one or more additional illustrative examples, the drain electrical contact 226 can include a Ti/Au-containing material. In one or more further illustrative examples, the drain electrical contact 226 can include a TiN-containing material. In various examples, the drain electrical contact 226 can be disposed within at least one of the first compound semiconductor layer 204, the second compound semiconductor layer 210 and the dielectric layer 212. The drain electrical contact 226 can have a base region 228 and a step region 230. The step region 230 can extend away from the base region 228 toward the gate electrical contact 220. The step region 230 can contribute to a relatively low resistance junction between the drain electrical contact 226 and the second compound semiconductor layer 210.

A first 2-dimensional electron gas (2DEG) layer 232 can be formed at the interface of the first compound semiconductor layer 204 and the second compound semiconductor layer 210 that enables the flow of electrons through the first 2DEG layer 232. In one or more examples, the first 2DEG layer 232 can be disposed between the source electrical contact 214 and the drain electrical contact 226. In one or more illustrative examples, the first 2DEG layer 232 can be formed at an interface of a first compound semiconductor layer 204 that is comprised of GaN and a second compound semiconductor layer 210 comprised of AlGaN. The first 2DEG layer 232 can be produced in response to an electric field generated during operation of the compound semiconductor device 200.

The compound semiconductor device 200 can also include a first conductive component 234. The first conductive component 234 can be disposed within the first compound semiconductor layer 204. In addition, the first conductive component 234 can be disposed in relation to the source electrical contact 214. In various examples, the first conductive component 234 can be disposed below a region that corresponds to the source electrical contact 214 and extends at least up to a terminus of the step region 218 of the source electrical contact 214. The first conductive component 234 can include one or more conductive materials. To illustrate, the first conductive component 234 can include AlN. Further, the first conductive component 234 can have a thickness from about 2 nm to about 100 nm, from about 25 nm to about 75 nm, from 10 nm to about 50 nm, or from about 2 nm to about 10 nm. At least a portion of the first conductive component 234 can directly contact the source electrical contact 214.

The compound semiconductor device 200 can also include a second conductive component 236. The second conductive component 236 can be disposed within the first compound semiconductor layer 204. In one or more examples, the second conductive component 236 can be disposed at least substantially parallel to the first conductive component 234. Additionally, the second conductive component 236 can be disposed in relation to the drain electrical contact 226. In various examples, the second conductive component 236 can be disposed below a region that corresponds to the drain electrical contact 226 and extends up to at least a terminus of the step region 230 of the drain electrical contact 226. In one or more implementations, the second conductive component 236 can extend beyond the drain electrical contact 226, but terminate prior to being aligned with a portion of the gate electrical contact 220. The second conductive component 236 can include one or more conductive materials. In one or more illustrative examples, the second conductive component 236 include AlN. The second conductive component 236 can have a thickness from about 2 nm to about 100 nm, from about 25 nm to about 75 nm, from 10 nm to about 50 nm, or from about 2 nm to about 10 nm. Further, at least a portion of the second conductive component 236 can directly contact the drain electrical contact 226.

A second 2DEG layer 238 can be produced in relation to the first conductive component 234. For example, the second 2DEG layer 238 can be produced with respect to an interface between the first conductive component 234 and the first compound semiconductor layer 204 in the presence of an electric field generated during operation of the compound semiconductor device 200. In addition, a third 2DEG layer 240 can be produced in relation to the second conductive component 236. To illustrate, the third 2DEG layer 240 can be produced with respect to an interface between the second conductive component 236 and the first compound semiconductor layer 204 in the presence of an electric field generated during operation of the compound semiconductor device 200.

The first conductive component 234 can be disposed a first distance 242 from the second compound semiconductor layer 210. In addition, the second conductive component 236 can be disposed a second distance 244 from the second compound semiconductor layer 210. In one or more examples, the first distance 242 can be approximately the same as the second distance 244. In one or more additional examples, the first distance 242 and the second distance 244 can be different. In various examples, the first distance 242 and the second distance 244 can be at least a first threshold distance and no greater than a second threshold distance.

The first threshold distance can correspond to a distance at which the first conductive component 234 does not cause depletion of the first 2DEG 232. For example, the first threshold distance can correspond to a distance where the first conductive component 234 causes no more than a minimum amount of reduction in the electron concentration of the 2DEG 232. Additionally, the first threshold distance can correspond to a distance at which the second 2DEG layer 238 and the third 2DEG layer 240 increase the electron concentration of the compound semiconductor device 200 in respective regions where the first 2DEG layer 232 overlaps (in a lateral direction in FIG. 2) with at least one of the second 2DEG layer 238 or the third 2DEG layer 240.

The second threshold distance can correspond to a distance at which the second 2DEG layer 238 and the third 2DEG layer 240 provide less than a minimum contribution to the electron concentration of the compound semiconductor device 200 in respective regions where the first 2DEG layer 232 overlaps (in a lateral direction in FIG. 2) with at least one of the second 2DEG layer 238 or the third 2DEG layer 240. In various examples, in scenarios where a conductive component is disposed greater than the second threshold distance from the second compound semiconductor layer 210, short channel effects can occur and the compound semiconductor device 200 can be difficult to turn off and it can be harder to prevent leakage of current between the source region and the drain region of the compound semiconductor device 200. In one or more illustrative examples, the first threshold distance can be from about 10 nm to about 30 nm and the second threshold distance can be from about 200 nm to about 250 nm. In one or more additional illustrative examples, the first distance 242 and the second distance can be from about 10 nm to about 250 nm, from about 20 nm to about 225 nm, from about 30 nm to about 200 nm, from about 50 nm to about 200 nm, from about 50 nm to about 175 nm, from about 75 nm to about 200 m, or from about 100 nm to about 200 nm.

In various examples, the first conductive component 234 can have a conductive component extension 246. The conductive component extension 246 can cause the first conductive component 234 to be disposed up to an edge of the gate electrical contact 220. In one or more examples, the conductive component extension 246 can result in a 2DEG layer extension 248 of the second 2DEG layer 238. The conductive component extension 246 can modify an electric field produced by the gate electrical contact 220. To illustrate, electric fields can have relatively greater values near an edge of a device. Thus, an electric field produced at the edges of the gate electrical contact 220 can have relatively greater values than the values of the electric field closer to a center of the gate electrical contact 220. The conductive component extension 246 can decrease the value of the electric field produced by the gate electrical contact 220 proximate to the edge of the gate electrical contact 220 that corresponds to the source electrical contact 214.

Further, in implementations where the second conductive component 236 is disposed up to or near the edge of the gate electrical contact 220 proximate to the drain electrical contact 226, the second conductive component 236 can reduce the value of the electric field produced by the gate electrical contact 220 near the edge of the gate electrical contact 220 proximate to the drain electrical contact 226. The reduction in the values of the electric field proximate to one or more edges of the gate electrical contact 220 can make the compound semiconductor device 200 suitable for use in high voltage radio frequency integrated circuits.

In the illustrative example of FIG. 2, a first enhanced region of electron concentration can be produced in a region of the first compound semiconductor layer 204 that is proximate to the source electrical contact 214 due to the presence of the first 2DEG layer 232 and the second 2DEG layer 238. A second enhanced region of electron concentration can be produced in a region of the first compound semiconductor layer 204 that is proximate to the drain electrical contact 226 due to the presence of the first 2DEG layer 232 and the third 2DED layer 240. In one or more examples, the first enhanced region of electron concentration can also extend from the region of the first compound semiconductor layer 204 that is proximate to the source electrical contact 214 toward a region of the first compound semiconductor layer 204 that aligns with the gate electrical contact 220. Additionally, the second enhanced region of electron concentration can extend from the region of the first compound semiconductor layer 204 proximate to the drain electrical contact 226 toward the region of the first compound semiconductor layer 204 that aligns with the gate electrical contact 220. In these scenarios, the regions of enhanced electron concentration can have electrical characteristics that are similar to n⁺ doped regions of existing silicon-based semiconductor devices. To illustrate, the contact resistance and source resistance in the region of the first compound semiconductor layer 204 that is proximate to the first conductive component 234 and the source electrical contact 214 can be less than in existing compound semiconductor devices. The lowering of the source resistance can flatten the transconductance of the compound semiconductor device 200 resulting in more linear operation of the compound semiconductor device 200. Further, the contact resistance and the drain resistance in the region of the first compound semiconductor layer 204 that is proximate to the second conductive component 236 and the drain electrical contact 226 can be less than in existing compound semiconductor devices.

Additionally, the region of the first compound semiconductor layer 204 that is aligned with the gate electrical contact 220 can have a relatively lower concentration of electrons than the enhanced regions of electron concentration that correspond to the locations of the first conductive component 234 and the second conductive component 236. In these instances, the region of the first compound semiconductor layer 204 that is aligned with the gate electrical contact 220 can have electrical characteristics that are similar to n⁻ doped regions of existing silicon-based semiconductor devices.

Although not shown in the illustrative example of FIG. 2, the compound semiconductor device 200 can include additional electronic components. For example, compound semiconductor device 200 can include one or more resistors. In addition, the compound semiconductor device 200 can include one or more capacitors. Further, the compound semiconductor device 200 can include one or more front-side field plates disposed on or within the dielectric layer 212. The compound semiconductor device 200 can also include one or more inductors. In various examples, the compound semiconductor device 200 can include one or more interconnect devices.

Further, the compound semiconductor device 200 can include one or more additional conductive components (not shown in FIG. 2) that are configured as back-side field plates. The one or more additional conductive components can be located a distance from the second compound semiconductor layer 210 that is greater than the second threshold distance. For example, the one or more additional conductive components can be located at least about 250 nm from an interface of the first compound semiconductor layer 204 and the second compound semiconductor layer 210. In one or more examples, the one or more additional conductive components can be disposed within the first compound semiconductor layer 204. In one or more additional examples, the one or more additional conductive components can be disposed in another layer of the compound semiconductor device 200, such as the substrate 202. In one or more implementations that include the one or more additional conductive components, the one or more additional conductive components can modify one or more electric fields produced during operation of the compound semiconductor device 200. In one or more further examples, an amount of current carried by the one or more additional conductive components can be minimized. That is, the one or more additional conductive components can be shorted with respect to the source of the compound semiconductor device 200.

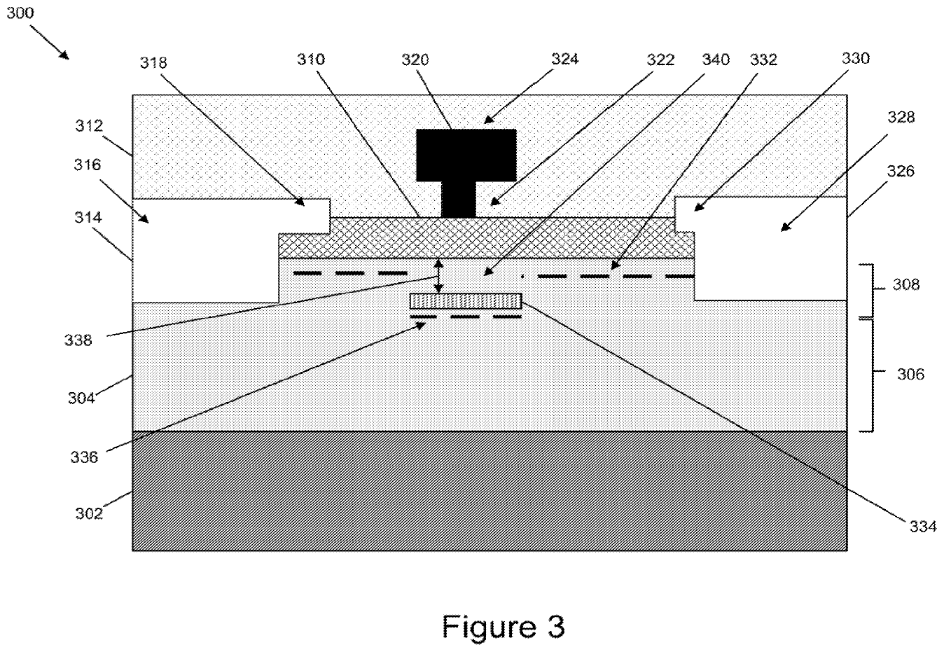

FIG. 3 is a diagram depicting a cross-section of at least a portion of components of an additional example compound semiconductor device 300 including a conductive component to control electrical characteristics of a compound semiconductor device 300. The compound semiconductor device 300 can include some similar features with respect to the compound semiconductor device 200 described with respect to FIG. 2. In one or more implementations, the compound semiconductor device 300 can differ from the compound semiconductor device 200 in relation to a location of at least one conductive component to control electrical characteristics of the compound semiconductor device 300.

The compound semiconductor device 300 can include a substrate 302. The substrate 302 can be an SiC-containing substrate. The substrate 302 can also include an Si-containing substrate. Further, the substrate 302 can include a sapphire substrate. In one or more examples, the substrate 302 can include an aluminum nitride-(AlN) containing substrate. A thickness of the substrate 302 can be from about 100 micrometers to about 800 micrometers, from about 200 micrometers to about 700 micrometers, or from about 300 micrometers to about 600 micrometers.

A first compound semiconductor layer 304 can be disposed on the substrate 302. The first compound semiconductor layer 304 can be a channel layer of the compound semiconductor device 300. The first compound semiconductor layer 304 can have a thickness from about 250 nm to about 1500 nm, from about 400 nm to about 1200 nm, from about 500 nm to about 1000 nm, from about 100 nm to about 500 nm, from about 100 nm to about 300 nm, or from about 30 nm to about 250 nm. The first compound semiconductor layer 304 can include one or more compound semiconductors. The one or more compound semiconductors of the first compound semiconductor layer 304 can include a group of elements having at least one element from Group 13 of the periodic table of elements and at least one element from Group 15 of the periodic table of elements. For example, the first compound semiconductor layer 304 can include GaN. In addition, the first compound semiconductor layer 304 can include GaAs. Further, the first compound semiconductor layer 304 can include AlN. The first compound semiconductor layer 304 can also include InP.

The first compound semiconductor layer 304 can include a first section 306 and a second section 308. The first section 306 can be formed initially and then one or more conductive components can be formed in the first section 306. After forming the first section 306, the second section 308 can be formed on the first section 306. The first section 306 and the second section 308 can have different characteristics. For example, the first section 306 can include a first concentration of dopants and the second section 308 can include a second concentration of dopants. To illustrate, the first section 306 can include a first concentration of carbon dopants and the second section 308 can include a second concentration of carbon dopants that is less than the first concentration of dopants of the first section 306. Additionally, the first section 306 and the second section 308 can include different dopants. In one or more illustrative examples, the first section 306 can include carbon dopants and the second section 308 can include silicon dopants. The differences in dopants or dopant concentration between the first section 306 and the second section 308 can minimize leakage of charge in the first compound semiconductor layer 304.

Further, the first section 306 can have a thickness that is different from a thickness of the second section 308. For example, the first section 306 can have a thickness from about 200 nm to about 1300 nm, from about 300 nm to about 1000 nm, from about 400 nm to about 800 nm, or from about 100 nm to about 500 nm. In one or more illustrative examples, the second section 308 can have a thickness from about 20 nm to about 400 nm, from about 50 nm to about 300 nm, from about 100 nm to about 250 nm, from about 50 nm to about 200 nm.

In various examples, the first section 306 can be epitaxially grown on the substrate 302. Additionally, the second section 308 can be epitaxially grown on the first section 306. Although not shown in the illustrative example of FIG. 3, a nucleation layer can be disposed on the substrate 302 and the first section 306 can be grown on the nucleation layer. The nucleation layer can have a thickness from about 10 nanometers to about 200 nanometers, from about 20 nanometers to about 100 nanometers, or from about 20 nanometers to about 80 nanometers. The nucleation layer can include an AlN-containing material.

A second compound semiconductor layer 310 can be disposed on at least a portion of the first compound semiconductor layer 304. The second compound semiconductor layer 310 can include one or more compound semiconductors. The one or more compound semiconductors can include a group of elements having at least one element from Group 13 of the periodic table of elements and at least one element from Group 15 of the periodic table of elements. For example, the second compound semiconductor layer 310 can be an AlGaN barrier layer, in various implementations. The second compound semiconductor layer 310 can also be an AlInGaN barrier layer. In addition, the second compound semiconductor layer 310 can have a thickness from about 20 nm to about 120 nm, from about 30 nm to about 100 nm, from about 40 nm to about 80 nm, or from about 20 nm to about 60 nm.

A dielectric layer 312 can be disposed on at least a portion of the second compound semiconductor layer 310. The first dielectric layer 312 can include a SiN-containing material. Although not shown in the illustrative example of FIG. 3, at least one additional dielectric layer can be disposed over the dielectric layer 312. For example, at least one additional dielectric layer can include a SiO₂ material, in one or more implementations. The at least one additional dielectric layer can also include a Si₂N₃ material or a Si₃N₄ material, in one or more additional implementations.

A source electrical contact 314 can be disposed over a source region of the compound semiconductor device 300. The source electrical contact 314 can include one or more suitable metallic materials. For example, the source electrical contact 314 can include at least one of titanium (Ti), aluminum (Al), nickel (Ni), or gold (Au). In one or more illustrative examples, the source electrical contact 314 can include a Ti/Al-containing material. In one or more additional illustrative examples, the source electrical contact 314 can include a Ti/Au-containing material. In one or more further illustrative examples, the source electrical contact 314 can include a TiN-containing material. In various examples, the source electrical contact 314 can be disposed within at least one of the first compound semiconductor layer 304, the second compound semiconductor layer 310 and the dielectric layer 312. The source electrical contact 314 can have a base region 316 and a step region 318. The step region 318 can extend away from the base region 316 toward a gate electrical contact 320. The step region 318 can contribute to a relatively low resistance junction between the source electrical contact 314 and the second compound semiconductor layer 310.

The gate electrical contact 320 can be disposed over a gate region of the second compound semiconductor layer 310. The gate electrical contact 320 can include one or more suitable metallic materials. For example, the gate electrical contact 320 can include a titanium nitride (TiN)/Al material. The gate electrical contact 320 can also include a nickel (Ni)/gold (Au) material. Additionally, the gate electrical contact 320 can include a TiN material. In various examples, the gate electrical contact 320 can have a T-like shape with a base region 322 and a transverse portion 324 that is disposed at least substantially perpendicular with respect to the base region 322.

Further, a drain electrical contact 326 can be disposed over a drain region of the compound semiconductor device 300. The drain electrical contact 326 can include one or more suitable metallic materials. To illustrate, the drain electrical contact 326 can include at least one of titanium (Ti), aluminum (Al), nickel (Ni), or gold (Au). In one or more illustrative examples, the drain electrical contact 326 can include a Ti/Al-containing material. In one or more additional illustrative examples, the drain electrical contact 326 can include a Ti/Au-containing material. In one or more further illustrative examples, the drain electrical contact 326 can include a TiN-containing material. In various examples, the drain electrical contact 326 can be disposed within at least one of the first compound semiconductor layer 304, the second compound semiconductor layer 310 and the dielectric layer 312. The drain electrical contact 326 can have a base region 328 and a step region 330. The step region 330 can extend away from the base region 328 toward the gate electrical contact 320. The step region 330 can contribute to a relatively low resistance junction between the drain electrical contact 326 and the second compound semiconductor layer 310.

A first 2-dimensional electron gas (2DEG) layer 332 can be formed at a portion of the interface of the first compound semiconductor layer 304 and the second compound semiconductor layer 310 that enables the flow of electrons through the first 2DEG layer 332. In one or more examples, the first 2DEG layer 332 can be disposed between the source electrical contact 314 and the drain electrical contact 326. In one or more illustrative examples, the first 2DEG layer 332 can be formed at a portion of an interface of a first compound semiconductor layer 304 that is comprised of GaN and a second compound semiconductor layer 310 comprised of AlGaN. The first 2DEG layer 332 can be produced in response to an electric field generated during operation of the compound semiconductor device 300.

The compound semiconductor device 300 can also include a conductive component 334. The conductive component 334 can be disposed within the first compound semiconductor layer 304. In addition, the conductive component 334 can be disposed in relation to the gate electrical contact 320. In various examples, the conductive component 334 can be disposed below a region that corresponds to the gate electrical contact 320 and extends from a first edge of the transverse portion 324 proximate to the source electrical contact 314 to a second edge of the transverse portion 324 proximate to the drain electrical contact 326. The conductive component 334 can include one or more conductive materials. To illustrate, the conductive component 334 can include AlN. Further, the conductive component 334 can have a thickness from about 2 nm to about 100 nm, from about 25 nm to about 75 nm, from 10 nm to about 50 nm, or from about 2 nm to about 10 nm. A second 2DEG layer 336 can be produced in relation to the conductive component 334. For example, the second 2DEG layer 336 can be produced with respect to an interface between the conductive component 334 and the first compound semiconductor layer 304 in the presence of an electric field generated during operation of the compound semiconductor device 300.

The conductive component 334 can be disposed a distance 338 from the second compound semiconductor layer 310. In one or more examples, the distance 338 can be no greater than a threshold distance from the second compound semiconductor layer 310. The threshold distance can correspond to a distance at which the conductive component 334 at least partially depletes the first 2DEG layer 332. For example, the conductive component 334 can be disposed no greater than a distance from the second compound semiconductor layer 310 such that an electron concentration of the first 2DEG layer 332 is reduced by at least about 50% with respect to portions of the first 2DEG layer 332 that are not aligned with the conductive component 334, at least about 75% with respect to portions of the first 2DEG layer 332 that are not aligned with the conductive component 334, at least about 85% with respect to portions of the first 2DEG layer 332 that are not aligned with the conductive component 334, at least about 90% with respect to portions of the first 2DEG layer 332 that are not aligned with the conductive component 334, at least about 95% with respect to portions of the first 2DEG layer 332, or at least about 99% with respect to portions of the first 2DEG layer 332 that are not aligned with the conductive component 334. In one or more illustrative examples, the electron concentration of the first 2DEG layer 332 can be reduced from about 1×10¹⁵ to 1×10²⁰ electrons per cm² in one or more portions of the first 2DEG layer 332 that are not aligned with the conductive component 334 to about 1×10¹⁰ to 1×10¹⁴ electrons per cm² in one or more portions of the first 2DEG layer that are aligned with the conductive component 334. In one or more examples, a gap region 340 can be present in the first 2DEG layer 332 based on a depletion of the first 2DEG layer 332 due to a proximity of the conductive component 334 with respect to the first 2DEG layer 332. In one or more illustrative examples, the distance 338 can be from about 10 nm to about 75 nm, from about 10 nm to about 50 nm, from about 10 nm to about 45 nm, from about 10 nm to about 40 nm, or from about 10 nm to about 30 nm.

In the illustrative example of FIG. 3, a reduction in electron concentration of the first 2DEG layer 332 in the gap region 340 can enable the compound semiconductor device 300 to operate as an enhancement mode device. In various examples, depletion of the first 2DEG layer 332 in the gap region 340 can cause an increase in threshold voltage of the compound semiconductor device 300 in relation to compound semiconductor devices in which the electron concentration below the gate electrical contact 320 is not depleted by a conductive component. Thus, locating the conductive component 334 within a threshold distance of the second compound semiconductor layer 310 can produce an electron concentration profile that has similarities with respect to enhancement mode devices that are comprised of typical silicon-based semiconductor devices that utilize dopants to deplete the concentration of electrons below a gate electrical contact.

Although not shown in the illustrative example of FIG. 3, the compound semiconductor device 300 can include additional electronic components. For example, compound semiconductor device 300 can include one or more resistors. In addition, the compound semiconductor device 300 can include one or more capacitors. Further, the compound semiconductor device 300 can include one or more front-side field plates disposed on or within the dielectric layer 312. The compound semiconductor device 300 can also include one or more inductors. In various examples, the compound semiconductor device 300 can include one or more interconnect devices.

Further, the compound semiconductor device 300 can include one or more additional conductive components (not shown in FIG. 3) that are configured as back-side field plates. The one or more additional conductive components can be located a distance from the second compound semiconductor layer 310 that is greater than an additional threshold distance. For example, the one or more additional conductive components can be located at least about 250 nm from the second compound semiconductor layer 310. In one or more examples, the one or more additional conductive components can be disposed within the first compound semiconductor layer 304. In one or more additional examples, the one or more additional conductive components can be disposed in another layer of the compound semiconductor device 300, such as the substrate 302. In one or more implementations that include the one or more additional conductive components, the one or more additional conductive components can modify one or more electric fields produced during operation of the compound semiconductor device 300. In one or more further examples, an amount of current carried by the one or more additional conductive components can be minimized. That is, the one or more additional conductive components can be shorted with respect to the source of the compound semiconductor device 300.

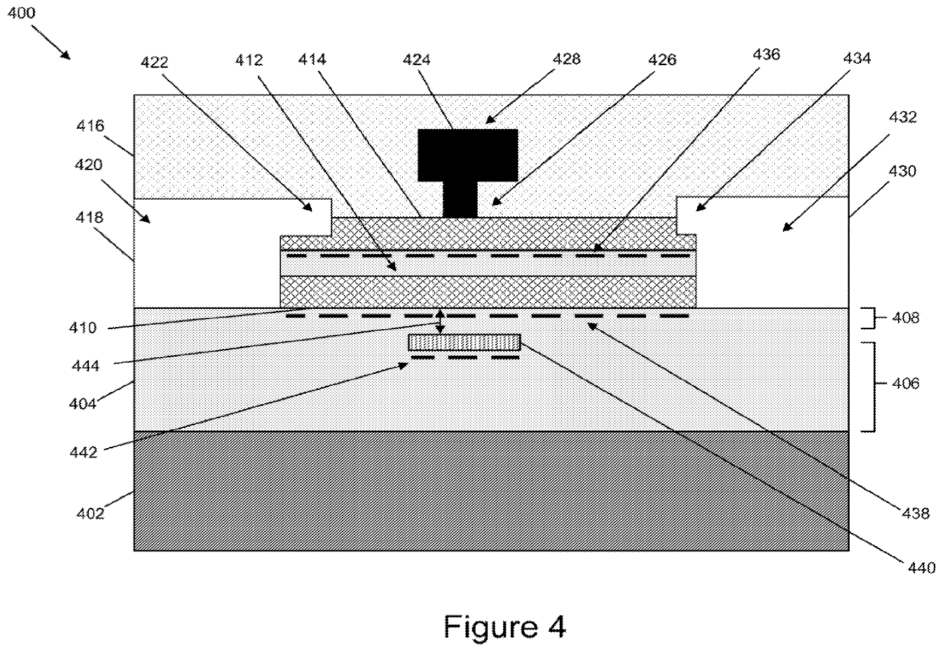

FIG. 4 is a diagram depicting a cross-section of at least a portion of components of an additional example compound semiconductor device 400 including multiple barrier layers and having a conductive component to control electrical characteristics of the compound semiconductor device 400. The compound semiconductor device 400 can include some similar features with respect to the compound semiconductor device 200 described with respect to FIG. 2.

The substrate 402 can be an SiC-containing substrate. The substrate 402 can also include an Si-containing substrate. Further, the substrate 402 can include a sapphire substrate. In one or more examples, the substrate 402 can include an aluminum nitride-(AlN) containing substrate. A thickness of the substrate 402 can be from about 100 micrometers to about 800 micrometers, from about 200 micrometers to about 700 micrometers, or from about 300 micrometers to about 600 micrometers.

A first compound semiconductor layer 404 can be disposed on the substrate 402. The first compound semiconductor layer 404 can be a channel layer of the compound semiconductor device 400. The first compound semiconductor layer 404 can have a thickness from about 250 nm to about 1500 nm, from about 400 nm to about 1200 nm, from about 500 nm to about 1000 nm, from about 100 nm to about 500 nm, from about 100 nm to about 300 nm, or from about 30 nm to about 250 nm. The first compound semiconductor layer 404 can include one or more compound semiconductors. The one or more compound semiconductors of the first compound semiconductor layer 404 can include a group of elements having at least one element from Group 13 of the periodic table of elements and at least one element from Group 15 of the periodic table of elements. For example, the first compound semiconductor layer 404 can include GaN. In addition, the first compound semiconductor layer 404 can include GaAs. Further, the first compound semiconductor layer 404 can include AlN. The first compound semiconductor layer 404 can also include InP. In various examples, the first compound semiconductor layer 404 can be a first channel layer.

The first compound semiconductor layer 404 can include a first section 406 and a second section 408. The first section 406 can be formed initially and then one or more conductive components can be formed in the first section 406. After forming the first section 406, the second section 408 can be formed on the first section 406. The first section 406 and the second section 408 can have different characteristics. For example, the first section 406 can include a first concentration of dopants and the second section 408 can include a second concentration of dopants. To illustrate, the first section 406 can include a first concentration of carbon dopants and the second section 408 can include a second concentration of carbon dopants that is less than the first concentration of dopants of the first section 406. Additionally, the first section 406 and the second section 408 can include different dopants. In one or more illustrative examples, the first section 406 can include carbon dopants and the second section 408 can include silicon dopants. The differences in dopants or dopant concentration between the first section 406 and the second section 408 can minimize leakage of charge in the first compound semiconductor layer 404.

Further, the first section 406 can have a thickness that is different from a thickness of the second section 408. For example, the first section 406 can have a thickness from about 200 nm to about 1300 nm, from about 300 nm to about 1000 nm, from about 400 nm to about 800 nm, or from about 100 nm to about 500 nm. In one or more illustrative examples, the second section 408 can have a thickness from about 20 nm to about 400 nm, from about 50 nm to about 300 nm, from about 100 nm to about 250 nm, from about 50 nm to about 200 nm.

In various examples, the first section 406 can be epitaxially grown on the substrate 402. Additionally, the second section 408 can be epitaxially grown on the first section 406. Although not shown in the illustrative example of FIG. 4, a nucleation layer can be disposed on the substrate 402 and the first section 406 can be grown on the nucleation layer. The nucleation layer can have a thickness from about 10 nanometers to about 200 nanometers, from about 20 nanometers to about 100 nanometers, or from about 20 nanometers to about 80 nanometers. The nucleation layer can include an AlN-containing material.

A second compound semiconductor layer 410 can be disposed on at least a portion of the first compound semiconductor layer 404. The second compound semiconductor layer 410 can include one or more compound semiconductors. The one or more compound semiconductors can include a group of elements having at least one element from Group 13 of the periodic table of elements and at least one element from Group 15 of the periodic table of elements. For example, the second compound semiconductor layer 410 can be an AlGaN barrier layer, in various implementations. The second compound semiconductor layer 410 can also be an AlInGaN barrier layer. In addition, the second compound semiconductor layer 410 can have a thickness from about 20 nm to about 120 nm, from about 30 nm to about 100 nm, from about 40 nm to about 80 nm, from about 2 nm to about 10 nm, from about 2 nm to about 120 nm, or from about 20 nm to about 60 nm. In one or more illustrative examples, the second compound semiconductor layer 410 can have a thickness from about 5 nm to about 15 nm when the second compound semiconductor layer 410 comprises AlGaN. In one or more additional illustrative examples, the second compound semiconductor layer 410 can have a thickness from about 2 nm to about 10 nm when the second compound semiconductor layer 410 comprises AlN.

A third compound semiconductor layer 412 can be disposed on at least a portion of the second compound semiconductor layer 410. The third compound semiconductor layer 412 can have characteristics that are similar to those of the first compound semiconductor layer 404. For example, the third compound semiconductor layer 412 can include one or more compound semiconductors. The one or more compound semiconductors of the third compound semiconductor layer 412 can include a group of elements having at least one element from Group 13 of the periodic table of elements and at least one element from Group 15 of the periodic table of elements. For example, the third compound semiconductor layer 412 can include GaN. In addition, the third compound semiconductor layer 412 can include GaAs. Further, the third compound semiconductor material 412 can include AlN. The third compound semiconductor material layer 412 can also include InP. In one or more examples, the third compound semiconductor layer 412 can include one or more dopants. To illustrate, the third compound semiconductor layer 412 can include one or more carbon dopants or one or more silicon dopants. In various examples, the third compound semiconductor layer 412 can be a second channel layer. The third compound semiconductor layer 412 can have a thickness from about 20 nm to about 120 nm, from about 30 nm to about 100 nm, from about 40 nm to about 80 nm, or from about 20 nm to about 60 nm.

Additionally, a fourth compound semiconductor layer 414 can be disposed on at least a portion of the third compound semiconductor layer 412. The fourth compound semiconductor layer 414 can include one or more compound semiconductors. The one or more compound semiconductors can include a group of elements having at least one element from Group 13 of the periodic table of elements and at least one element from Group 15 of the periodic table of elements.

For example, the fourth compound semiconductor layer 414 can be an AlGaN barrier layer, in various implementations. The fourth compound semiconductor layer 414 can also be an AlInGaN barrier layer. In various examples, In addition, the fourth compound semiconductor layer 414 can have a thickness from about 20 nm to about 120 nm, from about 30 nm to about 100 nm, from about 40 nm to about 80 nm, from about 2 nm to about 10 nm, from about 2 nm to about 120 nm, or from about 20 nm to about 60 nm. In one or more illustrative examples, the fourth compound semiconductor layer 414 can have a thickness from about 5 nm to about 15 nm when the fourth compound semiconductor layer 414 comprises AlGaN. In one or more additional illustrative examples, the fourth compound semiconductor layer 414 can have a thickness from about 2 nm to about 10 nm when the second compound semiconductor layer 410 comprises AlN.

A dielectric layer 416 can be disposed on at least a portion of the fourth compound semiconductor layer 414. The dielectric layer 416 can include a SiN-containing material. Although not shown in the illustrative example of FIG. 4, at least one additional dielectric layer can be disposed over the dielectric layer 416. For example, at least one additional dielectric layer can include a SiO₂ material, in one or more implementations. The at least one additional dielectric layer can also include a Si₂N₃ material, in one or more additional implementations.

A source electrical contact 418 can be disposed over a source region of the compound semiconductor device 400. The source electrical contact 418 can include one or more suitable metallic materials. For example, the source electrical contact 418 can include at least one of titanium (Ti), aluminum (Al), nickel (Ni), or gold (Au). In one or more illustrative examples, the source electrical contact 418 can include a Ti/Al-containing material. In one or more additional illustrative examples, the source electrical contact 418 can include a Ti/Au-containing material. In one or more further illustrative examples, the source electrical contact 418 can include a TiN-containing material. In various examples, the source electrical contact 418 can be disposed within at least one of the first compound semiconductor layer 404, the second compound semiconductor layer 410, the third compound semiconductor layer 412, the fourth compound semiconductor layer 414, and the dielectric layer 416. The source electrical contact 418 can have a base region 420 and a step region 422. The step region 422 can extend away from the base region 420 toward a gate electrical contact 424. The step region 422 can contribute to a relatively low resistance junction between the source electrical contact 418 and the fourth compound semiconductor layer 414.

The gate electrical contact 424 can be disposed over a gate region of the compound semiconductor device 400. The gate electrical contact 424 can include one or more suitable metallic materials. For example, the gate electrical contact 424 can include a titanium nitride (TiN)/Al material. The gate electrical contact 424 can also include a nickel (Ni)/gold (Au) material. Additionally, the gate electrical contact 424 can include a TiN material. In various examples, the gate electrical contact 424 can have a T-like shape with a base region 426 and a transverse portion 428 that is disposed at least substantially perpendicular with respect to the base region 426.

Further, a drain electrical contact 430 can be disposed over a drain region of the compound semiconductor device 400. The drain electrical contact 430 can include one or more suitable metallic materials. To illustrate, the drain electrical contact 430 can include at least one of titanium (Ti), aluminum (Al), nickel (Ni), or gold (Au). In one or more illustrative examples, the drain electrical contact 430 can include a Ti/Al-containing material. In one or more additional illustrative examples, the drain electrical contact 430 can include a Ti/Au-containing material. In one or more further illustrative examples, the drain electrical contact 430 can include a TiN-containing material. In various examples, the drain electrical contact 430 can be disposed within at least one of the first compound semiconductor layer 404, the second compound semiconductor layer 410, the third compound semiconductor layer 412, the fourth compound semiconductor layer 414, and the dielectric layer 416. The drain electrical contact 430 can have a base region 432 and a step region 434. The step region 434 can extend away from the base region 432 toward the gate electrical contact 424. The step region 434 can contribute to a relatively low resistance junction between the drain electrical contact 430 and the fourth compound semiconductor layer 414.

A first 2-dimensional electron gas (2DEG) layer 436 can be formed at the interface of the third compound semiconductor layer 412 and the fourth compound semiconductor layer 414 that enables the flow of electrons through the first 2DEG layer 436. In one or more examples, the first 2DEG layer 436 can be disposed between the source electrical contact 418 and the drain electrical contact 430. In one or more illustrative examples, the first 2DEG layer 436 can be formed at an interface of the third compound semiconductor layer 412 that is comprised of GaN and the fourth compound semiconductor layer 414 comprised of AlGaN. The first 2DEG layer 436 can be produced in response to an electric field generated during operation of the compound semiconductor device 400.

Additionally, a second 2-dimensional electron gas (2DEG) layer 438 can be formed at the interface of the first compound semiconductor layer 404 and the second compound semiconductor layer 410 that enables the flow of electrons through the second 2DEG layer 438. In one or more examples, the second 2DEG layer 438 can be disposed between the source electrical contact 418 and the drain electrical contact 430. In one or more illustrative examples, the second 2DEG layer 438 can be formed at an interface of the first compound semiconductor layer 404 that is comprised of GaN and the second compound semiconductor layer 410 comprised of AlGaN. The second 2DEG layer 438 can be produced in response to an electric field generated during operation of the compound semiconductor device 400.

The compound semiconductor device 400 can also include a conductive component 440. The conductive component 440 can be disposed within the first compound semiconductor layer 404. In addition, the conductive component 440 can be disposed in relation to the gate electrical contact 424. In various examples, the conductive component 440 can be disposed below a region that corresponds to the gate electrical contact 424 and extends from a first edge of the transverse portion 428 proximate to the source electrical contact 418 to a second edge of the transverse portion 428 proximate to the drain electrical contact 430. The conductive component 440 can include one or more conductive materials. To illustrate, the conductive component 440 can include AlN Further, the conductive component 440 can have a thickness from about 2 nm to about 100 nm, from about 25 nm to about 75 nm, from 10 nm to about 50 nm, or from about 2 nm to about 10 nm.

A third 2DEG layer 442 can be produced in relation to the conductive component 440. For example, the third 2DEG layer 442 can be produced with respect to an interface between the conductive component 440 and the first compound semiconductor layer 404 in the presence of an electric field generated during operation of the compound semiconductor device 400. The conductive component 440 can be disposed a distance 444 from the second compound semiconductor layer 410. In one or more examples, the distance 444 can be no greater than a threshold distance from the second compound semiconductor layer 410. The threshold distance can correspond to a distance at which the conductive component 440 can be configured as a second gate electrical contact. That is, the voltage applied to the gate electrical contact 424 can control the current in the first 2DEG layer 436 from the source electrical contact 418 to the drain electrical contact 430 and a voltage applied to the conductive component 440 can control the current in the second 2DEG layer 438 from the source electrical contact 418 to the drain electrical contact 430. In this way, the compound semiconductor device 400 can be configured as a dual channel semiconductor device that includes a first channel layer comprised of the first compound semiconductor layer 404 and a second channel layer comprised of the third compound semiconductor layer 412 and a dual gate semiconductor device that includes a first gate comprised of the gate electrical contact 424 and a second gate comprised of the conductive component 440.

Although not shown in the illustrative example of FIG. 4, the compound semiconductor device 400 can include additional electronic components. For example, compound semiconductor device 400 can include one or more resistors. In addition, the compound semiconductor device 400 can include one or more capacitors. Further, the compound semiconductor device 400 can include one or more front-side field plates disposed on or within the dielectric layer 416. The compound semiconductor device 400 can also include one or more inductors. In various examples, the compound semiconductor device 400 can include one or more interconnect devices.

Further, the compound semiconductor device 400 can include one or more additional conductive components (not shown in FIG. 4) that are configured as back-side field plates. The one or more additional conductive components can be located a distance from the second compound semiconductor layer 410 that is greater than an additional threshold distance. For example, the one or more additional conductive components can be located at least about 250 nm from the second compound semiconductor layer 410. In one or more examples, the one or more additional conductive components can be disposed within the first compound semiconductor layer 404. In one or more additional examples, the one or more additional conductive components can be disposed in another layer of the compound semiconductor device 400, such as the substrate 402. In one or more implementations that include the one or more additional conductive components, the one or more additional conductive components can modify one or more electric fields produced during operation of the compound semiconductor device 400. In one or more further examples, an amount of current carried by the one or more additional conductive components can be minimized. That is, the one or more additional conductive components can be shorted with respect to the source of the compound semiconductor device 400.

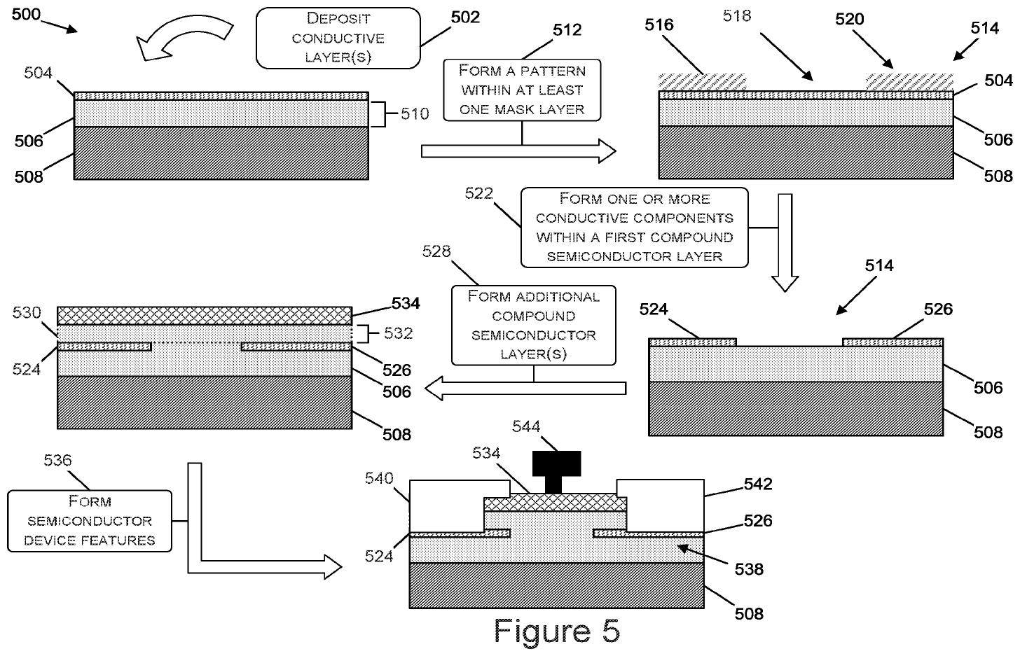

FIG. 5 is a diagram depicting an example process 500 to form one or more conductive components in a compound semiconductor layer. The process 500 can include, at 502 depositing one or more conductive layers. For example, a conductive layer 504 can be deposited on at least a portion of a first section of a first compound semiconductor layer 506. In one or more examples, at least a portion of the first section of the first compound semiconductor layer 506 can be etched prior to forming the conductive layer 504. Subsequent to one or more etching processes, the conductive layer 504 can be formed using one or more deposition processes. In one or more illustrative examples, the conductive layer 504 can be formed using metal-organic chemical vapor deposition or hybrid vapor phase epitaxy. In one or more further examples, the conductive layer 504 can be formed using molecular beam epitaxy. Additionally, the conductive layer 504 can be comprised of one or more metallic materials. In one or more illustrative examples, the conductive layer can be comprised of an AlN-containing material.

The first section of the first compound semiconductor layer 506 can include one or more compound semiconductors. The one or more compound semiconductors can include at least one element from Group 13 of the periodic table of elements and at least one element from Group 15 of the periodic table of elements. The first section of the first compound semiconductor layer 506 can comprise a channel layer. In one or more illustrative examples, the first section of the first compound semiconductor layer 506 can include GaN. In addition, the first section of the first compound semiconductor layer 506 can include GaAs. Further, the first section of the first section of the first compound semiconductor layer 506 can include AlN. The first section of the first compound semiconductor layer 506 can also include InP. The first section of the first section of the first compound semiconductor layer 506 can have a thickness 510. For example, the thickness 510 of the first section of the first compound semiconductor layer 506 can be from about 200 nm to about 1300 nm, from about 300 nm to about 1000 nm, from about 400 nm to about 800 nm, or from about 100 nm to about 500 nm.

The first section of the first compound semiconductor layer 506 can be formed on a substrate 508 using one or more epitaxial growth processes. In various examples, the first section of the first compound semiconductor layer 506 can be formed using molecular beam epitaxy. Further, the first section of the first compound semiconductor layer 506 can be formed using hybrid vapor phase epitaxy. In one or more examples, the substrate 508 can comprise a Si-containing substrate. In one or more additional examples, the substrate 508 can comprise a SiC-containing substrate. In one or more further examples, the substrate 508 can comprise a sapphire substrate.

At 512, the process 500 can include forming a pattern within at least one mask layer. For example, a pattern 514 can be formed using portions of a mask layer 516. In one or more examples, the pattern 514 can be formed using one or more etching processes. In implementations where the mask layer 516 includes a photoresist material, the pattern 514 can be formed using one or more processes to expose the mask layer 516 to one or more ranges of electromagnetic radiation that correspond to the pattern 514 followed by one or more etching processes. The one or more etching processes can include one or more solution-based etching processes. In one or more additional examples, the one or more etching processes can include one or more dry etching processes. The pattern 514 can include one or more recessed regions, such as a recessed region 518. The pattern 514 can also include one or more raised regions, such as a raised region 520 that includes a portion of the mask layer 516.

The mask layer 516 can comprise a polymeric material. In one or more examples, the mask layer 516 can comprise a photoresist-containing material. In one or more additional examples, the mask layer 516 can comprise a dielectric material. To illustrate, the mask layer 516 can comprise a silicon nitride (SiN)-containing material. Additionally, the mask layer 516 can comprise a silicon dioxide (SiO₂)-containing material. In various examples, the mask layer 516 can be one of a plurality of mask layers. In implementations where the process 500 includes depositing a plurality of mask layers, a first mask layer can comprise a SiN-containing material and a second mask layer can comprise a SiO₂-containing material.

The process 500 can also include, at 522, forming one or more conductive components within a first compound semiconductor layer. In the illustrative example of FIG. 5, a first conductive component 524 and a second conductive component 526 can be formed within the first section of the first compound semiconductor layer 506 according to the pattern 514. For example, the first conductive component 524 can be formed in relation to a first raised region of the pattern 514 and the second conductive component 526 can be formed in relation to a second raised region of the pattern 514. In one or more examples, the first conductive component 524 and the second conductive component 526 can be formed using one or more etching processes.

Additionally, the process 500 can include, at 528, forming one or more additional compound semiconductor layers. In various examples, prior to forming the one or more additional compound semiconductor layers, the mask layer 504 can be removed. In one or more additional examples, prior to forming the one or more additional compound semiconductor layers, a chemical mechanical polishing (CMP) process can be performed. The CMP process can produce a relatively uniform surface that is comprised of a surface of the first conductive component 524, a surface of the first compound semiconductor layer 504, and a surface of the second conductive component 526. In this way, preparation can be made for forming the one or more additional compound semiconductor layers.

In one or more examples, the one or more additional compound semiconductor layers can include a second section of the first compound semiconductor layer 530. The second section of the first compound semiconductor layer 530 can be comprised of one or more compound semiconductors. In various examples, the second section of the first compound semiconductor layer 530 can be comprised of the same semiconductors as the first section of the first compound semiconductor layer 530. For example, the one or more compound semiconductors can include at least one element from Group 13 of the periodic table of elements and at least one element from Group 15 of the periodic table of elements. The second section of the first compound semiconductor layer 530 can comprise a channel layer. In one or more illustrative examples, the second section of the first compound semiconductor layer 530 can include GaN. In addition, the second section of the first compound semiconductor layer 530 can include GaAs. Further, the second section of the first compound semiconductor layer 530 can include AlN. The second section of the first compound semiconductor layer 530 can also include InP. The second section of the first compound semiconductor layer 530 can have a thickness 532. The thickness 532 can be from about 20 nm to about 400 nm, from about 50 nm to about 300 nm, from about 100 nm to about 250 nm, from about 50 nm to about 200 nm.

In various examples, the first section of the first compound semiconductor layer 506 and the second section of the first compound semiconductor layer 530 can include a common material. To illustrate, the first section of the first compound semiconductor layer 506 and the second section of the first compound semiconductor layer 530 can both comprise GaN. In one or more examples, the first section of the first compound semiconductor layer 506 and the second section of the first compound semiconductor layer 530 can be comprised of at least about 95% by weight of GaN. The first section of the first compound semiconductor layer 506 and the second section of the first compound semiconductor layer 530 can have differences. For example, a dopant included in the first section of the first compound semiconductor layer 506 can be different from a dopant included in the second section of the first compound semiconductor layer 530. In one or more illustrative examples, the first section of the first compound semiconductor layer 506 can include one or more carbon dopants and the second section of the first compound semiconductor layer 530 can include one or more silicon dopants. Additionally, the first section of the first compound semiconductor layer 506 can have a thickness 510 that is greater than a thickness 532 of the second section of the first compound semiconductor layer 530.

Further, the one or more additional compound semiconductor layers formed in relation to 528 can include a second compound semiconductor layer 534. The second compound semiconductor layer 534 can include one or more compound semiconductors. The one or more compound semiconductors can include at least one element from Group 13 of the periodic table of elements and at least one element from Group 15 of the periodic table of elements. For example, the second compound semiconductor layer 534 can be an AlGaN barrier layer, in various implementations. The fourth compound semiconductor layer 534 can also be an AlInGaN barrier layer.

The process 500 can also include, at 536, forming semiconductor device features. For example, features of one or more transistors can be formed using the first compound semiconductor layer 538 and the second compound semiconductor layer 534. The first compound semiconductor layer 538 can be comprised of the first section of the first compound semiconductor layer 506 and the second section of the first compound semiconductor layer 530. In one or more illustrative examples, a high electron mobility transistor (HEMT) can be formed using the first compound semiconductor layer 538 and the second compound semiconductor layer 534.

In one or more examples, a source electrical contact 540 can be disposed over a source region and a drain electrical contact 542 can be disposed over a drain region. The source electrical contact 540 and the drain electrical contact 542 can include one or more metallic materials. To illustrate, the source electrical contact 540 and the drain electrical contact 542 can include a Ti/Al material. In one or more additional illustrative examples, the source electrical contact 540 and the drain electrical contact 542 can include a Ti/Au metallic material. In one or more further illustrative examples, the source electrical contact 540 and the drain electrical contact 542 can include a TiN metallic material. Additionally, a gate electrical contact 544 can be disposed over a gate region. The gate electrical contact 544 can include one or more metallic materials. For example, the gate electrical contact 544 can include a titanium nitride (TiN)/AI material. The gate electrical contact 544 can also include a nickel (Ni)/gold (Au) material.

The source electrical contact 540 can have a step-like shape with a base region and a step region extending away from the base region and toward the gate electrical contact 544. In one or more examples, the source electrical contact 540 can be formed by a first pattern and etching process of a portion of the second compound semiconductor layer 534 that corresponds to the base region and the step region of the source electrical contact 540. The first pattern and etching process can be followed by a second pattern and etching process. The second pattern and etching process can comprise patterning and etching the base region in the second compound semiconductor layer 534 and patterning and etching the base region in the first compound semiconductor layer 538.

In addition, the drain electrical contact 542 can have a step-like shape with a base region and step region extending away from the base region and toward the gate electrical contact 544. In various examples, the drain electrical contact 542 can be formed by a first pattern and etching process of a portion of the second compound semiconductor layer 534 that corresponds to the base region and the step region of the source electrical contact 542. The first pattern and etching process can be followed by a second pattern and etching process. The second pattern and etching process can comprise patterning and etching the base region in the second compound semiconductor layer 534 and patterning and etching the base region in the first compound semiconductor layer 538.

Although not shown in the illustrative example of FIG. 5, the process 500 can include one or more additional operations. For example, the process 500 can include forming one or more dielectric layers on at least one of the compound semiconductor layers 534, 538 or the semiconductor device features 540, 542, 544. The one or more dielectric layers can include a SiO₂-containing material, a Si₂N₃-containing material, a Si₃N₄-containing material, or a SiN-containing material. In addition, the process 500 can include forming one or more capacitors, one or more inductors, one or more interconnects, one or more impedance components, one or more combinations thereof, and the like. The process 500 can also include forming one or more field plates, such as one or more front side field plates disposed proximate to one or more of the electrical contacts 540, 542, 544 and/or one or more backside field plates disposed within the substrate 508 or within the first compound semiconductor layer 538 at a depth that is below the first conductive component 524 and the second conductive component 526. The one or more backside field plates can be configured to shape electric fields rather than modifying electron concentration in the manner of the first conductive component 524 and the second conductive component 526.

Further, the location of conductive components within the first compound semiconductor layer 538 can be different from those shown in the illustrative example of FIG. 5 based on changes to the pattern 514 that is formed from the mask layer 516. For example, the first conductive component 524 can extend further toward the gate electrical contact 544 by increasing the width of the first recessed region 516. Additionally, rather than two conductive components being disposed within the first compound semiconductor layer 538, the process 500 can be implemented to produce a single conductive component within the first compound semiconductor layer 538. To illustrate, a recessed region can be produced in the mask layer 516 that is aligned with the gate electrical contact 544 and raised regions can be formed in the pattern 514 that are aligned with the source electrical contact 540 and the drain electrical contact 542. In these scenarios, a conductive component can be produced that is under and aligned with the gate electrical contact 544 such that an arrangement corresponding to that shown in the illustrative example of FIG. 3 and the illustrative example of FIG. 4 can be produced.

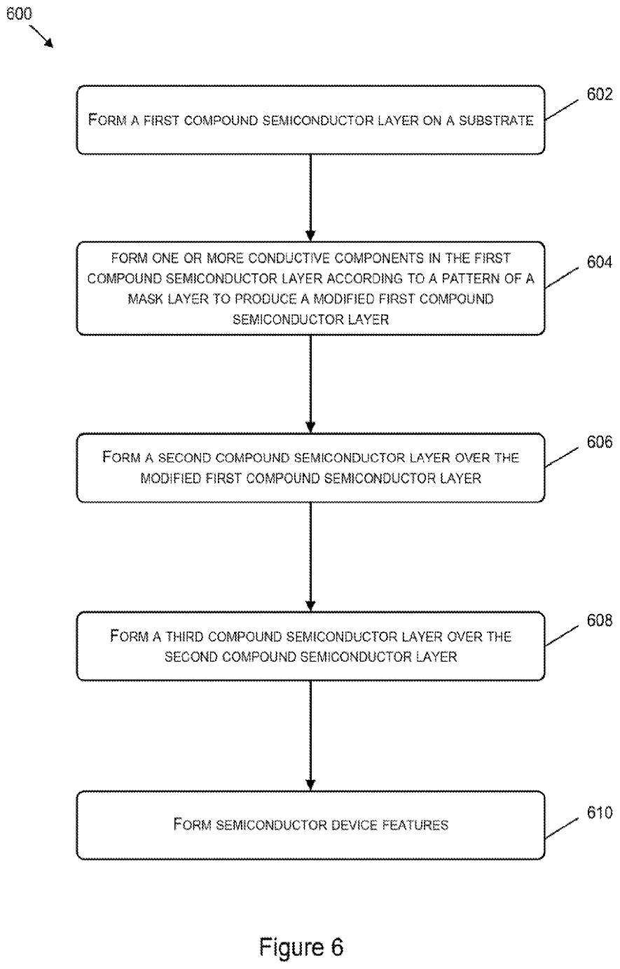

FIG. 6 is a flow diagram depicting operations of an example process 600 to form one or more conductive components in a compound semiconductor layer. At operation 602, the process 600 can include forming a first compound semiconductor layer on a substrate. The substrate can be an Si-containing substrate. In various examples, the substrate can be a SiC-containing substrate. The substrate can also comprise a sapphire-containing substrate. The first compound semiconductor layer can be comprised of a first compound semiconductor material including a first group of elements having one or more first Group 13 elements and one or more first Group 15 elements. In one or more illustrative examples, the first compound semiconductor layer can include GaN. In one or more implementations, the first compound semiconductor layer can include one or more dopants, such as one or more carbon dopants. The first compound semiconductor layer can be formed using one or more epitaxial growth processes. For example, the first compound semiconductor layer can be formed using molecular beam epitaxy or hybrid vapor phase epitaxy.

At 604, the process 600 can include forming one or more conductive components in the first compound semiconductor layer according to a pattern of a mask layer to produce a modified first compound semiconductor layer. The patterned mask layer can be formed by depositing one or more mask layers on the first compound semiconductor layer. The one or more mask layers can include one or more polymeric materials, such as a photoresist material. In one or more additional examples, the one or more mask layers can include one or more dielectric materials. The one or more mask layers can be shaped into a pattern using one or more etch processes.

In various examples, the pattern can correspond to placement of one or more conductive components within the first compound semiconductor layer. In one or more examples, the pattern can correspond to locating a conductive component in the first compound semiconductor layer that is aligned with a source electrical contact of a compound semiconductor device, locating a conductive component in the compound semiconductor layer that is aligned with a drain electrical contact of the compound semiconductor device, and producing a region of the first compound semiconductor layer that is aligned with a gate electrical contact of the compound semiconductor device and is free of a conductive component. In one or more additional examples, the pattern can correspond to locating a conductive component in the first compound semiconductor layer that is aligned with a gate electrical contact of a compound semiconductor device and producing regions of the first compound semiconductor layer that are free of a conductive component and that are aligned with a source electrical contact and a drain electrical contact of the compound semiconductor device.

In one or more examples, the one or more conductive components can be formed using one or more etching processes. For example, an etching solution can remove a portion of a conductive layer that is not covered by a portion of the mask layer. In various examples, a thermal activation process can be performed to etch the portion of the conductive layer not covered by a portion of the mask layer.

In one or more additional examples, the one or more conductive components can be formed using one or more implantation processes. The one or more implantation processes can include one or more ion implantation processes. For example, the one or more implantation processes can include one or more nitrogen ion implantation processes. In one or more additional examples, the one or more conductive components can be formed using one or more deposition processes. In various examples, the one or more conductive components can comprise AlN. The one or more conductive components can be formed in the first compound semiconductor layer in an environment and using different equipment from that used to form the first compound semiconductor layer. To illustrate, the first compound semiconductor layer can be formed in a reactor and to form the one or more conductive components, an apparatus including the first compound semiconductor layer disposed on the substrate can be removed from the reactor and the patterning of the mask layer in addition to the forming of the one or more conductive components can take place outside of the reactor.

In addition, at 606, the process 600 can include forming a second compound semiconductor layer over the modified first compound semiconductor layer. The second compound semiconductor layer can be formed within a reactor. In these scenarios, the second compound semiconductor layer can be placed back into the reactor used to form the first compound semiconductor layer after the one or more conductive components are formed within the first compound semiconductor layer in an environment outside of the reactor. In addition, prior to forming the second compound semiconductor layer, the modified first compound semiconductor layer can be subjected to one or more deoxidation processes, such as a hydrogen deoxidation process. In one or more illustrative examples, the second compound semiconductor layer can be formed using one or more epitaxial growth processes. For example, the second compound semiconductor layer can be formed using molecular beam epitaxy or hybrid vapor phase epitaxy.

The second compound semiconductor layer can be comprised of the first compound semiconductor material including the first group of elements having one or more first Group 13 elements and one or more first Group 15 elements. The one or more compound semiconductors included in the second compound semiconductor layer can include the same one or more compound semiconductors included in the first modified compound semiconductor layer. For example, the second compound semiconductor layer can comprise GaN and the first modified compound semiconductor layer can comprise GaN. In one or more examples, there can be one or more differences between the first modified compound semiconductor layer and the second compound semiconductor layer. To illustrate, the first modified compound semiconductor layer and the second compound semiconductor layer can both comprise GaN, but have different dopants. In one or more illustrative examples, the first modified compound semiconductor layer can include one or more carbon dopants and the second compound semiconductor layer can include one or more silicon dopants. In addition, the first compound semiconductor layer can have a thickness that is greater than a thickness of the second compound semiconductor layer. In various examples, the first compound semiconductor layer and the second compound semiconductor layer can form a channel layer with the first compound semiconductor layer comprising a first section of the channel layer and the second compound semiconductor layer comprising a second section of the channel layer.

Further, the process 600 can include, at operation 608, forming a third compound semiconductor layer over the second compound semiconductor layer.

The third compound semiconductor layer can include one or more compound semiconductors. The one or more compound semiconductors included in the third compound semiconductor layer can be different from the one or more compound semiconductors included in the first compound semiconductor layer and the second compound semiconductor layer. In various examples, the third compound semiconductor layer can be comprised of a second compound semiconductor material including a second group of elements having one or more first Group 13 elements and one or more first Group 15 elements. For example, the third compound semiconductor layer can include AlGaN. The third compound semiconductor layer can be formed using one or more epitaxial growth processes. To illustrate, the third compound semiconductor layer can be formed using molecular beam epitaxy or hybrid vapor phase epitaxy.

At operation 610, the process 600 can include forming semiconductor device features. The semiconductor device features can include components of a transistor. For example, the semiconductor device features can include a source electrical contact, a drain electrical contact, and a gate electrical contact. The semiconductor device features can also include one or more capacitors, one or more inductors, one or more interconnects, one or more impedance components, one or more electric field shaping components, one or more combinations thereof, and the like.

The location of the one or more conductive components can be based on characteristics of a compound semiconductor device that includes the one or more conductive components. For example, in implementations where a compound semiconductor device operates as an enhancement mode device, a conductive component can be located within a threshold distance of an interface between the second compound semiconductor layer and the third compound semiconductor layer such that the conductive component is aligned with the gate electrical contact and sufficiently close to the 2DEG formed at the interface of the second compound semiconductor layer and the third compound semiconductor layer to deplete the 2DEG underneath the gate electrical contact. In one or more examples, the conductive component can reduce the charge density of the 2DEG by at least about 50%. In these scenarios, the conductive component can be located at least about 10 nm and no greater than about 45 nm from the interface of the second compound semiconductor layer and the third compound semiconductor layer.

Additionally, in implementations, where a number of conductive components are configured to reduce the resistance corresponding to the source electrical contact and the drain electrical contact, the number of conductive components can be aligned with the source electrical contact and the drain electrical contact and be beyond an additional threshold distance from the interface between the second compound semiconductor layer and the third compound semiconductor layer. In these scenarios, the number of conductive components can be located at least about 50 nm from the interface of the second compound semiconductor layer and the third compound semiconductor layer. By locating the number of conductive components beyond the additional threshold distance, the 2DEG located at the intersection between the second compound semiconductor layer and the third compound semiconductor layer is minimally depleted and the charge density proximate to the source electrical contact and the drain electrical contact is increased.

In situations where the one or more conductive components are disposed in a compound semiconductor device that is an enhancement mode device, a thickness of the second compound semiconductor layer can be less than in scenarios where the conductive components are located farther from the interface of the second compound semiconductor layer and the third compound semiconductor layer. As a result, a conductive component can be located closer to the 2DEG at the interface of the second compound semiconductor layer and the third compound semiconductor layer in order to deplete the 2DEG. Further, the thickness of the second compound semiconductor layer can be increased in situations where conductive components are located farther away from the interface of the second compound semiconductor layer and the third compound semiconductor layer in order to increase the charge concentration and minimize depletion of the 2DEG at the interface of the second compound semiconductor layer and the third compound semiconductor layer.

A numbered non-limiting list of aspects of the present subject matter is presented below.
Aspect 1. A semiconductor device including one or more conductive components to control electrical characteristics of the semiconductor device, the semiconductor device comprising: a substrate; a first compound semiconductor layer disposed on a surface of the substrate, the first compound semiconductor layer being comprised of a first compound semiconductor material including a first group of elements having one or more first Group 13 elements and one or more first Group 15 elements; a second compound semiconductor layer disposed on the first compound semiconductor layer, the second compound semiconductor layer being comprised of a second compound semiconductor material including a second group of elements different from the first group of elements, the second group of elements having one or more second Group 13 elements and one or more second Group 15 elements, and a conductive component disposed within the first compound semiconductor layer and located a distance of at least about 10 nanometers (nm) from an interface of the first compound semiconductor layer and the second compound semiconductor layer.
Aspect 2. The semiconductor device of aspect 1, wherein the first compound semiconductor layer includes a first section and a second section, the first section including the conductive component and the second section being free of conductive components.
Aspect 3. The semiconductor device of aspect 2, wherein the first section includes a first dopant and the second section includes a second dopant that is different from the first dopant.
Aspect 4. The semiconductor device of aspect 3, wherein the first dopant includes a carbon dopant and the second dopant includes a silicon dopant.
Aspect 5. The semiconductor device of aspect 2, wherein the first section has a first thickness that is greater than a second thickness of the second section.
Aspect 6. The semiconductor device of any one of aspects 1-5, comprising a source electrical contact disposed over a source region, a gate electrical contact disposed over a gate region, and a drain electrical contact disposed over a drain region.
Aspect 7. The semiconductor device of aspect 6, wherein: the source electrical contact includes a first base region and a first step region, the first step region extending away from the first base region and toward the gate electrical contact; the first step region is disposed in the second compound semiconductor layer and the first base region is disposed in the first compound semiconductor layer and the second compound semiconductor layer; the drain electrical contact includes a second base region and a second step region, the second step region extending away from the second base region and toward the gate electrical contact; and the second step region is disposed in the second compound semiconductor layer and the second base region is disposed in the first compound semiconductor layer and the second compound semiconductor layer.
Aspect 8. The semiconductor device of aspect 6 or 7, wherein the conductive component is a first conductive component and the semiconductor device includes a second conductive component, the first conductive component being disposed in a first region of the first compound semiconductor layer that corresponds to the source electrical contact and the second conductive component being disposed in a second region of the first compound semiconductor layer that corresponds to the drain electrical contact.
Aspect 9. The semiconductor device of aspect 8, wherein a third region of the first compound semiconductor layer is disposed between the first region of the first compound semiconductor layer and the second region of the first compound semiconductor layer, the third region of the first compound semiconductor layer corresponding to the gate electrical contact, being free of the first conductive component, and being free of the second conductive component.
Aspect 10. The semiconductor device of aspect 9, wherein: a first two-dimensional electron gas (2DEG) layer is formed in relation to an interface of the first compound semiconductor layer and the second compound semiconductor layer; a second 2DEG layer is formed in relation to the first conductive component; and a third 2DEG layer is formed in relation to the second conductive component.
Aspect 11. The semiconductor device of aspect 10, wherein the first region and the third region have a charge density that is greater than an additional charge density of the second region.
Aspect 12. The semiconductor device of aspect 8, wherein the first conductive component and the second conductive component are disposed at least a threshold distance from an interface of the first compound semiconductor layer and the second compound semiconductor layer, the threshold distance being at least about 50 nm.
Aspect 13. The semiconductor device of aspect 12, wherein the first conductive component and the second conductive component are located approximately a same distance from the interface of the first compound semiconductor layer and the second compound semiconductor layer.
Aspect 14. The semiconductor device of aspect 6, wherein: the conductive component is disposed in a region of the first compound semiconductor layer that corresponds to the source electrical contact; and an edge of the conductive component extends up to an edge of the gate electrical contact that is proximate to the source electrical contact.
Aspect 15. The semiconductor device of any of aspects 1-5, wherein the conductive component is disposed in a region of the first compound semiconductor layer that corresponds to the gate electrical contact.
Aspect 16. The semiconductor device of aspect 15, wherein: a two-dimensional electron gas (2DEG) layer is formed in relation to an interface of the first compound semiconductor layer and the second compound semiconductor layer, and the conductive component depletes a portion of the 2DEG that corresponds to the gate electrical contact.
Aspect 17. The semiconductor device of aspect 15, wherein the semiconductor device is configured to operate as an enhancement mode device.
Aspect 18. The semiconductor device of aspect 14, wherein the conductive component is located no greater than a threshold distance from an interface of the first compound semiconductor layer and the second compound semiconductor layer, the threshold distance being no greater than about 45 nm.
Aspect 19. The semiconductor device of any one of aspects 1-7, further comprising: a third compound semiconductor layer disposed on the second compound semiconductor layer, the third compound semiconductor layer being comprised of the first compound semiconductor material including the first group of elements having the one or more first Group 13 elements and the one or more first Group 15 elements, and a fourth compound semiconductor layer disposed on the third compound semiconductor layer, the fourth compound semiconductor layer being comprised of the second compound semiconductor material including the second group of elements having the one or more second Group 13 elements and the one or more second Group 15 elements.
Aspect 20. The semiconductor device of aspect 19, wherein the conductive component is disposed in a region of the first compound semiconductor layer that corresponds to the gate electrical contact.
Aspect 21. The semiconductor device of any one of aspects 1-20, wherein: the first compound semiconductor layer comprises gallium nitride (GaN); the second compound semiconductor layer comprises aluminum gallium nitride (AlGaN); and the conductive component comprises aluminum nitride (AlN).
Aspect 22. A process to control electrical characteristics of a semiconductor device, the process comprising: forming a first compound semiconductor layer on a substrate, the first compound semiconductor layer being comprised of a first compound semiconductor material including a first group of elements having one or more first Group 13 elements and one or more first Group 15 elements; forming one or more conductive components in the first compound semiconductor layer according to a pattern of the patterned mask layer to produce a modified first compound semiconductor layer; forming a second compound semiconductor layer over the modified first compound semiconductor layer, the second compound semiconductor layer being comprised of the first compound semiconductor material including the first group of elements having the one or more first Group 13 elements and the one or more first Group 15 elements; and forming a third compound semiconductor layer over the second compound semiconductor layer, the third compound semiconductor layer being comprised of a second compound semiconductor material including a second group of elements different from the first group of elements, the second group of elements having one or more second Group 13 elements and one or more second Group 15 elements.
Aspect 23. The process of aspect 22, comprising forming a number of semiconductor device features including a source electrical contact, a gate electrical contact, and a dram electrical contact.
Aspect 24. The process of aspect 23, wherein the source electrical contact is formed by: etching a first portion of the third compound semiconductor layer that corresponds to a first portion of a base region of the source electrical contact and that corresponds to a step region of the source electrical contact, the step region extending away from the base region and towards the gate electrical contact; etching a second portion of the third compound semiconductor layer that corresponds to a second portion of the base region of the source electrical contact; etching a portion of the second compound semiconductor layer that corresponds to a third portion of the base region of the source electrical contact; and etching a portion of the first compound semiconductor layer that corresponds to a fourth portion of the base region of the source electrical contact.
Aspect 25. The process of aspect 23 or 24, wherein the drain electrical contact is formed by: etching a third portion of the third compound semiconductor layer that corresponds to a first portion of a base region of the drain electrical contact and that corresponds to a step region of the drain electrical contact, the step region extending away from the base region and towards the gate electrical contact; etching a fourth portion of the third compound semiconductor layer that corresponds to a second portion of the base region of the drain electrical contact; etching an additional portion of the second compound semiconductor layer that corresponds to a third portion of the base region of the drain electrical contact; and etching an additional portion of the first compound semiconductor layer that corresponds to a fourth portion of the base region of the drain electrical contact.
Aspect 26. The process of any one of aspects 23-25, wherein: the one or more conductive components include: a first conductive component that is disposed in a first region of the first compound semiconductor layer that corresponds to the source electrical contact; and a second conductive component that is disposed in a second region of the first compound semiconductor layer that corresponds to the drain electrical contact; and a third region of the first compound semiconductor layer is disposed between the first region and the second region and is free of the first conductive component and the second conductive component.
Aspect 27. The process of aspect 26, wherein the pattern includes: a first portion of the mask layer that corresponds to a location of the first conductive component; a second portion of the masked layer that corresponds to a location of the second conductive component; and a recessed region that is free of a portion of the mask layer and corresponds to the third region that is free of the first conductive component and free of the second conductive component.
Aspect 28. The process of any one of aspects 23-25, wherein the one or more conductive components include a conductive component that is disposed in a region of the first compound semiconductor layer that corresponds to the gate electrical contact.
Aspect 29. The process of aspect 28, wherein: the pattern includes a first portion recessed region disposed between a first recessed region and a second recessed region, the first recessed region and the second recessed region being free of the mask layer and the first portion corresponding to a location of the conductive component, the first recessed region corresponds to a location of the source electrical contact; and the second recessed region corresponds to a location the drain electrical contact.
Aspect 30. The process of any one of aspects 22-29, wherein the one or more conductive components are formed using one or more implantation processes.
Aspect 31. The process of any one of aspects 22-30, comprising: forming the first compound semiconductor layer using one or more epitaxial growth processes; forming the second compound semiconductor layer using one or more second epitaxial growth process after forming the one or more conductive components within the first compound semiconductor layer; and forming the third compound semiconductor layer using one or more third epitaxial growth processes.
Aspect 32. The process of any one of aspects 22-31, wherein the first compound semiconductor layer and the second compound semiconductor layer include gallium nitride (GaN) and the third compound semiconductor layer includes aluminum gallium nitride (AlGaN).
Aspect 33. A semiconductor device configured to control electrical characteristics of the semiconductor device, the semiconductor device comprising: a first compound semiconductor layer comprised of a first compound semiconductor material including a first group of elements having one or more first Group 13 elements and one or more first Group 15 elements; a second compound semiconductor layer comprised of a second compound semiconductor material including a second group of elements different from the first group of elements, the second group of elements having one or more second Group 13 elements and one or more second Group 15 elements; a source electrical contact disposed in relation to a source region of the semiconductor device; and a gate electrical contact disposed in relation to a gate region of the semiconductor device; wherein a first charge density is present in a first region of the first compound semiconductor layer that corresponds to the source electrical contact and a second charge density is present in a second region of the first compound semiconductor layer that corresponds to the gate electrical contact, the second charge density being less than the first charge density.
Aspect 34. The semiconductor device of aspect 33, wherein the second charge density is at least about 50% less than the first charge density
Aspect 35. The semiconductor device of aspect 33 or 34, wherein the source electrical contact is disposed in a portion of the first compound semiconductor layer and in a portion of the second compound semiconductor layer.
Aspect 36. The semiconductor device of any one of aspects 33-35, comprising a conductive component that is disposed in the first region of the first compound semiconductor layer, the conductive component contacting the source electrical contact.
Aspect 37. The semiconductor device of any one of aspects 33-36, comprising: a drain electrical contact disposed in relation to a drain region of the semiconductor device; wherein: a third charge density is present in a third region of the first compound semiconductor layer that corresponds to the drain electrical contact, the third charge density being greater than the second charge density; and the drain electrical contact is disposed in an additional portion of the first compound semiconductor layer and in an additional portion of the second compound semiconductor layer.
Aspect 38. The semiconductor device of aspect 37, comprising an additional conductive component that is disposed in the third region of the first compound semiconductor layer, the additional conductive component contacting the drain electrical contact.
Aspect 39. The semiconductor device of aspect 38, wherein the conductive component and the additional conductive component are located at least about 50 nanometers (nm) from an interface of the first compound semiconductor layer and the second compound semiconductor layer.
Aspect 40. A semiconductor device configured to control electrical characteristics of the semiconductor device, the semiconductor device comprising: a first compound semiconductor layer comprised of a first compound semiconductor material including a first group of elements having one or more first Group 13 elements and one or more first Group 15 elements; a second compound semiconductor layer comprised of a second compound semiconductor material including a second group of elements different from the first group of elements, the second group of elements having one or more second Group 13 elements and one or more second Group 15 elements; and agate electrical contact disposed in relation to a gate region of the semiconductor device; wherein a two-dimensional electron gas (2DEG) layer formed at an interface of the first compound semiconductor layer and the second compound semiconductor layer and the 2DEG layer is depleted in a region of the first compound semiconductor layer that corresponds the gate electrical contact.
Aspect 41. The semiconductor device of aspect 40, comprising a conductive component disposed in a region of the first compound semiconductor layer that is aligned with the gate electrical contact.
Aspect 42. The semiconductor device of aspect 41, wherein the conductive component is located no greater than about 45 nanometers (nm) from the interface of the first compound semiconductor layer and the second compound semiconductor layer.

Each of the non-limiting aspects or examples described herein may stand on its own or may be combined in various permutations or combinations with one or more of the other examples.

The above detailed description includes references to the accompanying drawings, which form a part of the detailed description. The drawings show, by way of illustration, specific embodiments in which the invention may be practiced. These implementations are also referred to herein as “examples.” Such examples may include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other implementations can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed implementation. Thus, the following claims are hereby incorporated into the Detailed Description as examples or implementations, with each claim standing on its own as a separate implementation, and it is contemplated that such implementations can be combined with each other in various combinations or permutations. The scope of the invention should be determined with reference to the appended claims, along with the full scope of equivalents to which such claims are entitled.

1. A semiconductor device including one or more conductive components to control electrical characteristics of the semiconductor device, the semiconductor device comprising:
a substrate;
a first compound semiconductor layer disposed on a surface of the substrate, the first compound semiconductor layer being comprised of a first compound semiconductor material including a first group of elements having one or more first Group 13 elements and one or more first Group 15 elements;
a second compound semiconductor layer disposed on the first compound semiconductor layer, the second compound semiconductor layer being comprised of a second compound semiconductor material including a second group of elements different from the first group of elements, the second group of elements having one or more second Group 13 elements and one or more second Group 15 elements; and
a conductive component disposed within the first compound semiconductor layer and located a distance of at least about 10 nanometers (nm) from an interface of the first compound semiconductor layer and the second compound semiconductor layer.

2. The semiconductor device of claim 1, wherein the first compound semiconductor layer includes a first section and a second section, the first section including the conductive component and the second section being free of conductive components.

3. The semiconductor device of claim 2, wherein the first section includes a first dopant and the second section includes a second dopant that is different from the first dopant.

4. The semiconductor device of claim 3, wherein the first dopant includes a carbon dopant and the second dopant includes a silicon dopant.

5. The semiconductor device of claim 2, wherein the first section has a first thickness that is greater than a second thickness of the second section.

6. The semiconductor device of claim 1, comprising a source electrical contact disposed over a source region, a gate electrical contact disposed over a gate region, and a drain electrical contact disposed over a drain region; and wherein:
the source electrical contact includes a first base region and a first step region, the first step region extending away from the first base region and toward the gate electrical contact;
the first step region is disposed in the second compound semiconductor layer and the first base region is disposed in the first compound semiconductor layer and the second compound semiconductor layer;
the drain electrical contact includes a second base region and a second step region, the second step region extending away from the second base region and toward the gate electrical contact; and
the second step region is disposed in the second compound semiconductor layer and the second base region is disposed in the first compound semiconductor layer and the second compound semiconductor layer.

7. The semiconductor device of claim 6, wherein the conductive component is a first conductive component and the semiconductor device includes a second conductive component, the first conductive component being disposed in a first region of the first compound semiconductor layer that corresponds to the source electrical contact and the second conductive component being disposed in a second region of the first compound semiconductor layer that corresponds to the drain electrical contact.

8. The semiconductor device of claim 7, wherein a third region of the first compound semiconductor layer is disposed between the first region of the first compound semiconductor layer and the second region of the first compound semiconductor layer, the third region of the first compound semiconductor layer corresponding to the gate electrical contact, being free of the first conductive component, and being free of the second conductive component.

9. The semiconductor device of claim 8, wherein:
a first two-dimensional electron gas (2DEG) layer is formed in relation to an interface of the first compound semiconductor layer and the second compound semiconductor layer;
a second 2DEG layer is formed in relation to the first conductive component;
a third 2DEG layer is formed in relation to the second conductive component and the first region and the third region have a charge density that is greater than an additional charge density of the second region.

10. (canceled)

11. The semiconductor device of claim 7, wherein the first conductive component and the second conductive component are disposed at least a threshold distance from an interface of the first compound semiconductor layer and the second compound semiconductor layer, the threshold distance being at least about 50 nm.

12. The semiconductor device of claim 6, wherein:
the conductive component is disposed in a region of the first compound semiconductor layer that corresponds to the source electrical contact; and
an edge of the conductive component extends up to an edge of the gate electrical contact that is proximate to the source electrical contact.

13. The semiconductor device gf claim 6, wherein the conductive component is disposed in a region of the first compound semiconductor layer that corresponds to the gate electrical contact.

14. The semiconductor device of claim 13, wherein:
a two-dimensional electron gas (2DEG) layer is formed in relation to an interface of the first compound semiconductor layer and the second compound semiconductor layer; and
the conductive component depletes a portion of the 2DEG that corresponds to the gate electrical contact.

15. The semiconductor device of claim 13, wherein the semiconductor device is configured to operate as an enhancement mode device.

16. The semiconductor device of claim 12, wherein the conductive component is located no greater than a threshold distance from an interface of the first compound semiconductor layer and the second compound semiconductor layer, the threshold distance being no greater than about 45 nm.

17. The semiconductor device of claim 1, wherein:
the first compound semiconductor layer comprises gallium nitride (GaN);
the second compound semiconductor layer comprises aluminum gallium nitride (AlGaN); and
the conductive component comprises aluminum nitride (AlN).

18. A process to control electrical characteristics of a semiconductor device, the process comprising:
forming a first compound semiconductor layer on a substrate, the first compound semiconductor layer being comprised of a first compound semiconductor material including a first group of elements having one or more first Group 13 elements and one or more first Group 15 elements;
forming one or more conductive components in the first compound semiconductor layer according to a pattern of a mask layer to produce a modified first compound semiconductor layer;
forming a second compound semiconductor layer over the modified first compound semiconductor layer, the second compound semiconductor layer being comprised of the first compound semiconductor material including the first group of elements having the one or more first Group 13 elements and the one or more first Group 15 elements; and
forming a third compound semiconductor layer over the second compound semiconductor layer, the third compound semiconductor layer being comprised of a second compound semiconductor material including a second group of elements different from the first group of elements, the second group of elements having one or more second Group 13 elements and one or more second Group 15 elements.

19. The process of claim 18, comprising forming a number of semiconductor device features including a source electrical contact, a gate electrical contact, and a drain electrical contact;
wherein the source electrical contact is formed by:
etching a first portion of the third compound semiconductor layer that corresponds to a first portion of a base region of the source electrical contact and that corresponds to a step region of the source electrical contact, the step region extending away from the base region and towards the gate electrical contact;
etching a second portion of the third compound semiconductor layer that corresponds to a second portion of the base region of the source electrical contact;
etching a portion of the second compound semiconductor layer that corresponds to a third portion of the base region of the source electrical contact; and
etching a portion of the first compound semiconductor layer that corresponds to a fourth portion of the base region of the source electrical contact; and
wherein the drain electrical contact is formed by:
etching a third portion of the third compound semiconductor layer that corresponds to a first portion of a base region of the drain electrical contact and that corresponds to a step region of the drain electrical contact, the step region extending away from the base region and towards the gate electrical contact;
etching a fourth portion of the third compound semiconductor layer that corresponds to a second portion of the base region of the drain electrical contact;
etching an additional portion of the second compound semiconductor layer that corresponds to a third portion of the base region of the drain electrical contact; and
etching an additional portion of the first compound semiconductor layer that corresponds to a fourth portion of the base region of the drain electrical contact.

20.-22. (canceled)

23. The process of claim 18, wherein the one or more conductive components are formed using one or more implantation processes.

24. The process of claim 18, comprising:
forming the first compound semiconductor layer using one or more epitaxial growth processes;
forming the second compound semiconductor layer using one or more second epitaxial growth process after forming the one or more conductive components within the first compound semiconductor layer; and
forming the third compound semiconductor layer using one or more third epitaxial growth processes.
